(19) United States
(12) Patent Application Publication
(10) Pub. No.: US 2025/0372507 A1
(43) Pub. Date: Dec. 4, 2025

(54) INTEGRATED CIRCUIT (IC) DEVICE, AND METHODS

(71) Applicant: TAIWAN SEMICONDUCTOR MANUFACTURING COMPANY, LTD., Hsinchu (TW)

(72) Inventors: Mohammed Zackriya VANAIKAR, Hsinchu (TW); Xiangdong CHEN, Hsinchu (TW); Yung-Chen CHIEN, Hsinchu (TW); Yu-Ting LIN, Hsinchu (TW)

(21) Appl. No.: 18/731,948

(22) Filed: Jun. 3, 2024

(51) Int. Cl. H01L 23/522; G06F 30/3953; H01L 21/768; H01L 23/528; H01L 27/02

(52) U.S. Cl. CPC H01L 23/5226; G06F 30/3953; H01L 21/768; H01L 23/5286; H10D 89/10

(57) ABSTRACT

An IC device includes a plurality of rows of semiconductor devices, and a metal layer. The rows are elongated along a first axis and side-by-side along a second axis transverse the first axis. The metal layer includes a plurality of conductors along a plurality of tracks elongated along the first axis. Each of the plurality of rows includes a first active region of a first conductivity type, and a second active region of a second conductivity type different from the first conductivity type, the second active region spaced from the first active region along the second axis. The plurality of rows includes first and second rows having a same first height along the second axis. The plurality of tracks includes first tracks in the first row, and second tracks in the second row. The first number of the first tracks differs from a second number of the second tracks.

### BACKGROUND

An integrated circuit (“IC”) device includes one or more semiconductor devices represented in an IC layout diagram (also referred to as “IC design layout diagram,” “layout diagram,” “IC layout,” or “layout”). A layout diagram is hierarchical and includes modules which carry out higher-level functions in accordance with the semiconductor device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs. Power, performance and area (PPA) are design considerations for IC devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a block diagram of an IC device, in accordance with some embodiments.

FIGS. 1B, 1C are schematic views, at various level, of a layout of a cell, in accordance with some embodiments.

FIG. 2 is a schematic cross-sectional view of a circuit region of an IC device, in accordance with some embodiments.

FIGS. 3A-3G are schematic views of layouts of circuit regions of one or more IC devices, in accordance with some embodiments.

FIGS. 4A-4D, 5A-5B, 6A-6B, 7A-7B are schematic views of IC layouts, in accordance with some embodiments.

FIGS. 8A-8C are flowcharts of various methods, in accordance with some embodiments.

FIGS. 9A, 9C, 9E are circuit diagrams of various cells, and FIGS. 9B, 9D, 9F are corresponding layouts of the cells in FIGS. 9A, 9C, 9E, in accordance with some embodiments.

FIG. 10 is a block diagram of an electronic design automation (EDA) system in accordance with some embodiments.

FIG. 11 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To generate an IC layout for an IC device, cells are read from one or more cell libraries, and placed in a plurality of rows (sometimes referred to as “cell rows”) of the IC layout, e.g., by an Automated Placement and Routing (APR) tool or system. In some embodiments, the rows have the same height (sometimes referred to as “row height”); however, at least one row has a metal pattern configuration (sometimes referred to as “metal scheme”) different from at least one other row. This arrangement is sometimes referred to as “mixed row configuration.” For example, in at least one embodiment, a row has a greater number of tracks for conductors of a metal layer, whereas another row of the same height has a smaller number of tracks for conductors of the same metal layer. In at least one embodiment, a row with a greater number of tracks is suitable for a complex cell, e.g., a cell with a number of interconnects greater than a predetermined number, because internal routing of the complex cell is simplified and/or efficient when the greater number of tracks is available. In at least one embodiment, a row with a smaller number of tracks is suitable for a non-complex cell, e.g., a cell with a number of interconnects not greater than the predetermined number, because the smaller number of tracks permits an increase of a width of and/or a spacing between conductors, with a corresponding decrease of resistance and/or capacitance (hereinafter “RC”), a corresponding increase of performance (or speed), and a corresponding reduction of IR drop (voltage drop).

In contrast, other approaches use the same number of tracks for a metal layer in all rows with the same height. As a result, in the other approaches, when the number of tracks is high, performance of non-complex cells is potentially impeded due to the reduced width and/or spacing of conductors, whereas when the number of tracks is low, internal routing of complex cells potentially becomes difficult and/or inefficient. A mixed row configuration in accordance with some embodiments provides an improvement over the other approaches, by achieving both efficient internal routing for complex cells and increased performance for non-complex cells. In some embodiments, a mixed row configuration comprises rows with more than two different metal pattern configurations correspondingly for more than two levels of cell complexity, to enhance a balance between internal routing efficiency and performance at various levels of cell complexity. Further features in accordance with various embodiments and corresponding advantages are also described herein.

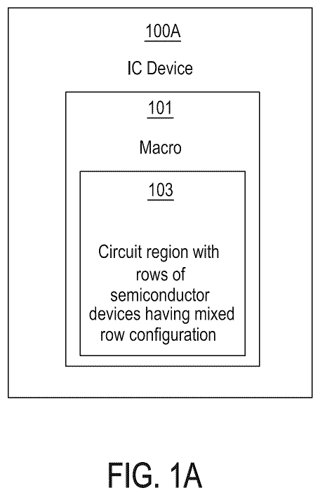

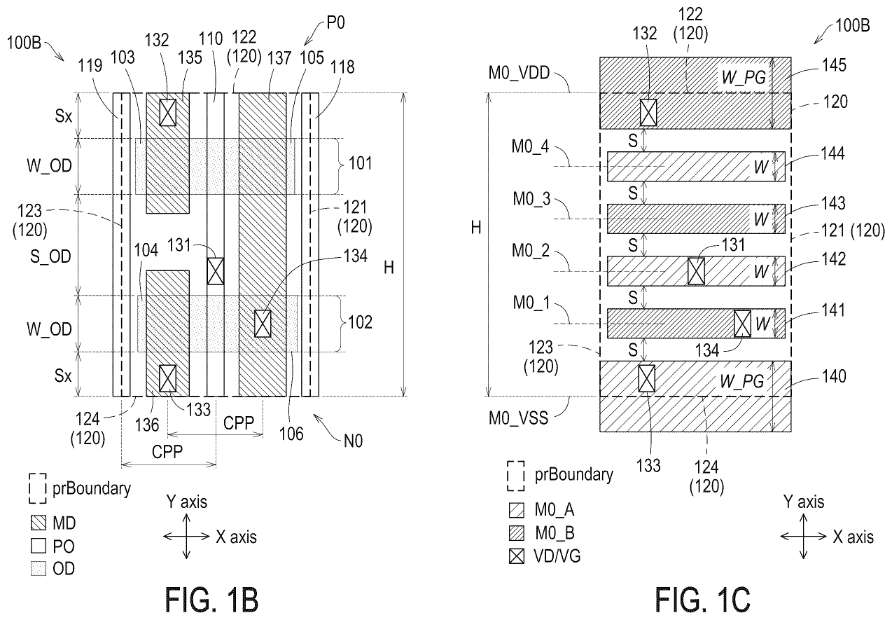

FIG. 1A is a block diagram of an IC device 100A, in accordance with some embodiments.

In FIG. 1, the IC device 100A comprises, among other things, a macro 101. In some embodiments, the macro 101 comprises one or more of a memory, a power grid, a cell or cells, an inverter, a latch, a buffer and/or any other type of circuit arrangement that may be represented digitally in a cell library. In some embodiments, the macro 101 is understood in the context of an analogy to the architectural hierarchy of modular programming in which subroutines/procedures are called by a main program (or by other subroutines) to carry out a given computational function. In this context, the IC device 100A uses the macro 101 to perform one or more given functions. Accordingly, in this context and in terms of architectural hierarchy, the IC device 100A is analogous to the main program and the macro 101 is analogous to subroutines/procedures. In some embodiments, the macro 101 is a soft macro. In some embodiments, the macro 101 is a hard macro. In some embodiments, the macro 101 is a soft macro which is described digitally in register-transfer level (RTL) code. In some embodiments, synthesis, placement and routing have yet to have been performed on the macro 101 such that the soft macro can be synthesized, placed and routed for a variety of process nodes. In some embodiments, the macro 101 is a hard macro which is described digitally in a binary file format (e.g., Graphic Database System II (GDSII) stream format), where the binary file format represents planar geometric shapes, text labels, other information and the like of one or more layout-diagrams of the macro 101 in hierarchical form. In some embodiments, synthesis, placement and routing have been performed on the macro 101 such that the hard macro is specific to a particular process node.

The macro 101 includes a circuit region 103, which comprises rows of semiconductor devices, wherein the rows are arranged in a mixed row configuration, as described herein. In some embodiments, the circuit region 103 comprises a substrate having circuitry formed thereon, in a front-end-of-line (FEOL) fabrication. Furthermore, above and/or below the substrate, the circuit region 103 comprises various metal layers that are stacked over and/or under insulating layers in a back-end-of-line (BEOL) fabrication. The BEOL provides routing for circuitry of the IC device 100A, including the macro 101 and the circuit region 103.

FIGS. 1B, 1C are schematic views, at various level, of a layout of a cell 100B, in accordance with some embodiments. FIG. 1B is a schematic view of semiconductor devices in the layout of the cell 100B. FIG. 1C is a schematic view of a metal layer over the semiconductor devices in the layout of the cell 100B. In some embodiments, the cell 100B corresponds to a circuit in the circuit region 103 described with respect to FIG. 1A. In at least one embodiment, the layout of the cell 100B is stored as a standard cell in a standard cell library on a non-transitory computer-readable medium.

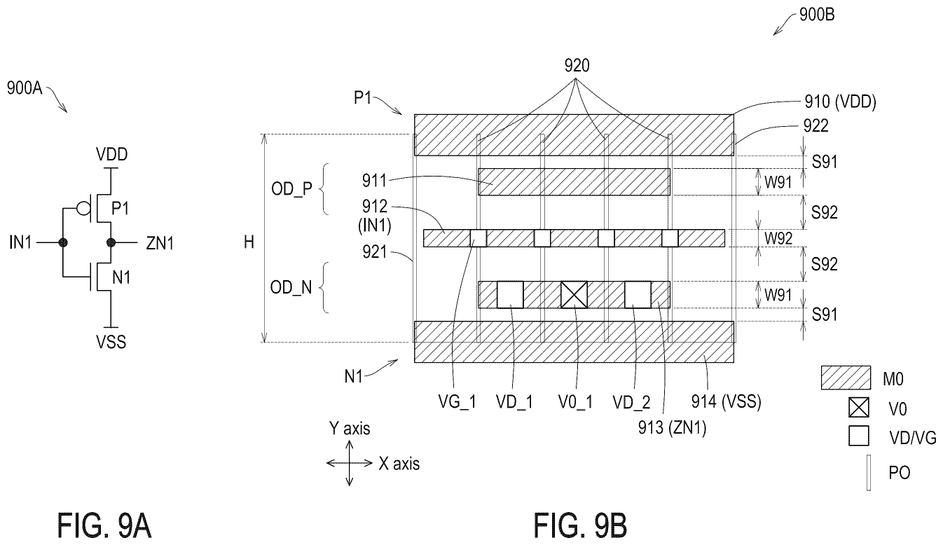

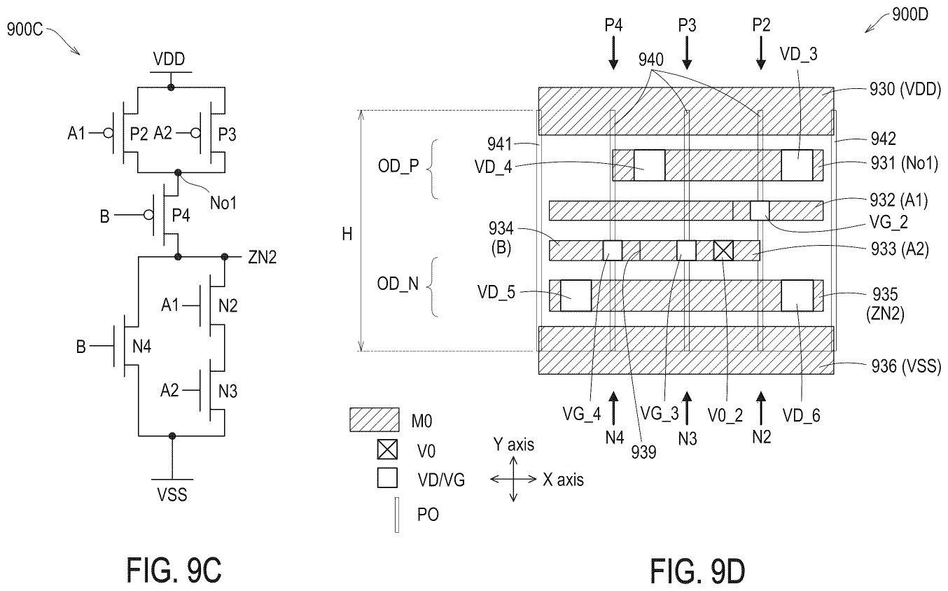

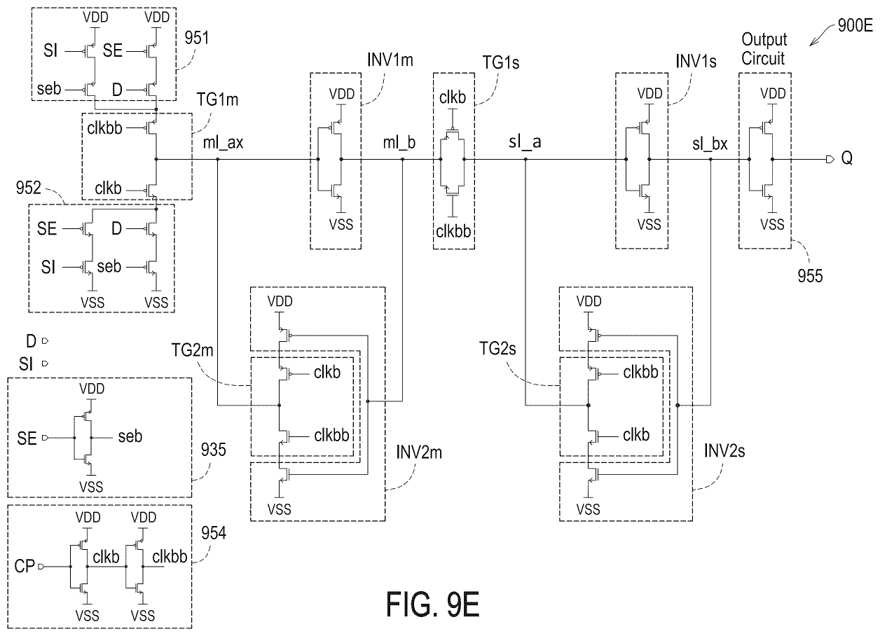

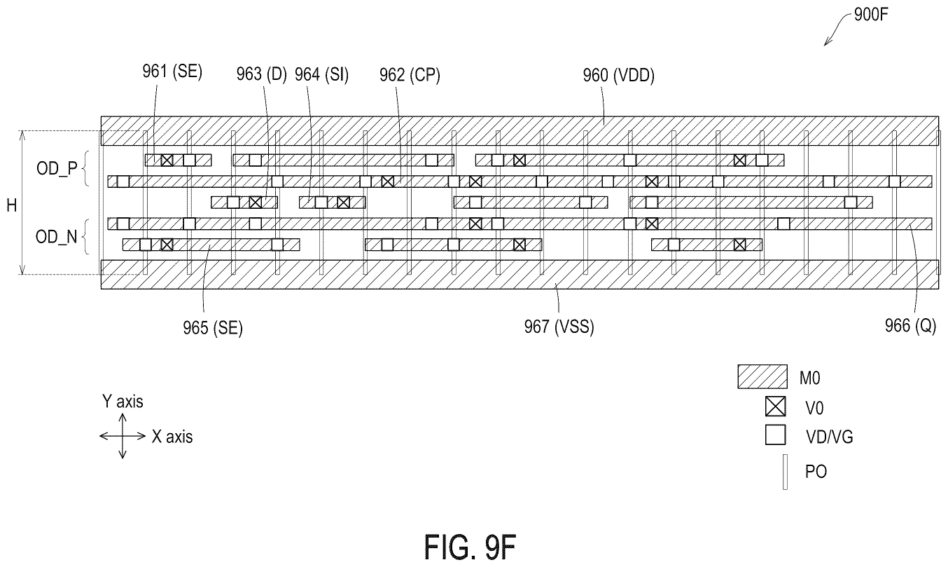

In the example configuration in FIGS. 1B, 1C, the cell 100B is an inverter having a circuit diagram described with respect to FIG. 9A. This is an example, and other cells are within the scope of various embodiments. Examples of cells include, but are not limited to, a logic gate cell, a memory cell, or the like. Examples of logic gate cells include, but are not limited to, AND, OR, NAND, NOR, XOR, INV, AND-OR-Invert (AOI), OR-AND-Invert (OAI), MUX, Flip-flop, BUFF, Latch, delay, clock, or the like. Examples of memory cells include, but are not limited to, a static random access memory (SRAM), a dynamic RAM (DRAM), a resistive RAM (RRAM), a magnetoresistive RAM (MRAM), a read only memory (ROM) cell, or another type of cell capable of having multiple states representative of logical values. In the example configuration in FIGS. 1B, 1C, the cell 100B is an inverter with a driving strength of 1. Other driving strengths, e.g., 2, 4, 6, or the like, are within the scopes of various embodiments. For example, an inverter of a driving strength of 4 is described with respect to FIG. 9B.

Referring to FIG. 1B, the cell 100B comprises first and second active regions, at least one gate region extending across the active regions, and a boundary in which the active regions and the at least one gate region are arranged. For example, the cell 100B comprises active regions 101, 102, a gate region 110, and a boundary 120.

The active regions 101, 102 extend along a first axis, i.e., X-axis. Active regions are sometimes referred to as oxide-definition (OD) regions, and are schematically illustrated in the drawings with the label “OD.” In an IC device comprising the cell 100B in accordance with at least one embodiment, the active regions 101, 102 are over a first side, or a front side, of a substrate as described herein. The active regions 101, 102 include P-type dopants and/or N-type dopants to form one or more circuit elements or semiconductor devices. Examples of circuit elements include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. An active region configured to form one or more PMOS devices therein is referred to herein as a “PMOS active region.” An active region configured to form one or more NMOS devices therein is referred to herein as an “NMOS active region.” In embodiments described herein, a PMOS active region is replaceable with an NMOS active region, and vice versa.

The gate region 110 extends across the active regions 101, 102 along a second axis, i.e., Y-axis, which is transverse to the X-axis. In at least one embodiment, the Y-axis is perpendicular to the X-axis. The gate region 110 includes a conductive material, such as, polysilicon, and is schematically illustrated in the drawings with the label “PO.” Other conductive materials for the gate region, such as metals, are within the scope of various embodiments.

In the example configuration in FIG. 1B, the active region 101 is a PMOS active region configured to form, together with the gate region 110, a transistor PO of the inverter. The active region 102 is an NMOS active region configured to form, together with the gate region 110, a transistor NO of the inverter. Specifically, the active region 101 comprises source/drain regions 103, 105 on opposite sides of a first section of the gate region 110 which extends over the active region 101. The active region 102 comprises source/drain regions 104, 106 on opposite sides of a second section of the gate region 110.

The boundary 120 comprises edges 121, 122, 123, 124 connected together to form a closed boundary. In a place-and-route operation (also referred to as “automated placement and routing (APR)”) described herein, cells are placed in an IC layout in abutment with each other at their respective boundaries. For example, the cell 100B is placed in abutment with one or more other cells along the X-axis at one or more of the edges 121, 123. Additionally or alternatively, the cell 100B is placed in abutment with one or more other cells along the Y-axis at one or more of the edges 122, 124. The boundary 120 is sometimes referred to as “place-and-route boundary” and is schematically illustrated in the drawings with the label “prBoundary.” The edges 121, 122, 123, 124 of the boundary 120 are sometimes referred to as boundary lines. In the example configuration in FIG. 1B, the boundary 120 has a rectangular shape, with the edges 121, 123 parallel to the Y-axis, and the edges 122, 124 parallel to the X-axis. Other configurations are within the scopes of various embodiments. For example, in one or more embodiments, the boundary 120 has a shape other than a rectangle shape and/or one or more edges of the boundary 120 are oblique with respect to the X-axis and the Y-axis.

The cell 100B further comprises dummy gate regions 118, 119 along the corresponding edges 121, 123 of the boundary 120. In at least one embodiment, centerlines of the dummy gate regions 118, 119 coincide with the corresponding edges 121, 123 of the boundary 120. The gate region 110 is an example of “functional gate regions” which, together with the underlying active regions, configure transistors and/or are electrically coupled to one or more other circuit elements. Unlike functional gate regions, dummy gate regions, or non-functional gate regions, are not configured to form transistors together with underlying active regions, and/or one or more transistors formed by dummy gate regions together with the underlying active regions are not electrically coupled to other circuit elements. In at least one embodiment, dummy gate regions include dielectric material in a manufactured IC device. Dummy gate regions and functional gate regions are arranged at the same pitch CPP, i.e., a center-to-center distance, along the X-axis. In a place-and-route operation when the cell 100B is placed to abut other cells, the dummy gate regions 118, 119 along the edges 121, 123 of the boundary 120 are merged with corresponding dummy gate regions of the other cells. Other configurations are within the scopes of various embodiments. For example, in one or more embodiments, one or more of the edges 121, 123 of the boundary 120 are not arranged along the dummy gate regions 118, 119.

The described configuration of the cell 100B comprising two active regions 101, 102 immediately adjacent (or directly adjacent) each other along the Y-axis is an example. Other cells in various embodiments include other numbers of active regions arranged along the Y-axis. Two active regions are immediately adjacent along the Y-axis when there is no other active region therebetween. In the example configuration in FIG. 1B, each of the active regions 101, 102 has, along the X-axis, opposite edges (not numbered) inwardly spaced from the corresponding edges 121, 123 of the boundary 120. Other configurations are within the scope of various embodiments. For example, in one or more embodiments, the active regions 101, 102 have, along the X-axis, the opposite edges coinciding with the corresponding edges 121, 123 of the boundary 120. The cell 100B comprises a functional gate region 110. This is an example, and other cells in various embodiments include multiple functional gate regions.

The cell 100B has a height (or cell height) H which is a distance along the Y-axis between the edges 122, 124 of the boundary 120. Each of the active regions 101, 102 has a width W_OD, sometimes referred to as “active region width,” along the Y-axis. In some embodiments, the active region width W_OD is predetermined by, and depends on, the corresponding cell height H as well as one or more design rules. An example design rule is a predetermined minimal spacing S_OD, along the Y-axis, between immediately adjacent active regions. A further example design rule is a predetermined minimal spacing Sx, along the Y-axis, between an active region and the closest edge (or boundary line) of the boundary 120. For example, as illustrated in FIG. 1B, the spacing S_OD is between the facing edges of the immediately adjacent active regions 101, 102, the spacing Sx is between the boundary line 122 and a facing edge (i.e., the upper edge in FIG. 1B) of the active region 101, and the spacing Sx is also between the boundary line 124 and a facing edge (i.e., the lower edge in FIG. 1B) of the active region 102. In some embodiments, S_OD=2Sx. Other design rules are within the scopes of various embodiments. In some embodiments, given the cell height H, W_OD is a maximal active region width of the active regions 101, 102 when all design rules are met.

The cell 100B further comprises contact structures over and in electrical contact with the corresponding source/drain regions in the active regions 101, 102. Contact structures are sometimes referred to as metal-to-device structures, and are schematically illustrated in the drawings with the label “MD.” An MD contact structure includes a conductive material formed over a corresponding source/drain region in the corresponding active region to define an electrical connection from one or more devices formed in the active region to other circuitry. In the example configuration in FIG. 1B, MD contact structures 135, 136 are over and in electrical contact with the corresponding source/drain regions 103, 104, and an MD contact structure 137 extends continuously along the Y-axis to be over and in electrical contact with both corresponding source/drain regions 105, 106. The MD contact structure 137 electrically couples the source/drain regions 105, 106 together. The MD contact structure 137 is an example of an extended contact structure that extends over multiple active regions. In some embodiments, an extended contact structure is in electrical contact with all the underlying active regions. In one or more embodiments, an extended contact structure is in electrical contact with at least one of the underlying active regions, while flying over without electrical contact with the other underlying active region(s). MD contact structures and gate regions (including both functional and dummy gate regions) are arranged alternatingly along the X-axis. A pitch, i.e., a center-to-center distance along the X-axis, between immediately adjacent MD contact structures is the same as the pitch CPP between immediately adjacent gate regions. Two gate regions (including functional and/or dummy gate regions) are considered immediately adjacent along the X-axis where there is no other gate region (including a functional gate region or a dummy gate region) therebetween. Two MD contact structures are considered immediately adjacent along the X-axis where there is no other MD contact structure therebetween. An example conductive material of MD contact structures includes metal. Other configurations are within the scopes of various embodiments.

The cell 100B further comprises vias over and in electrical contact with the corresponding gate regions or MD contact structures. A via over and in electrical contact with an MD contact structure is sometimes referred to as via-to-device (VD). A via over and in electrical contact with a gate region is sometimes referred to as via-to-gate (VG). VD and VG vias are schematically illustrated in the drawings with the label “VD/VG.” In the example configuration in FIGS. 1B, 1C, a VG via 131 is over and in electrical contact with the gate region 110, and VD vias 132, 133, 134 are correspondingly over and in electrical contact with the MD contact structures 135, 136, 137. An example material of the VD and VG vias includes metal. Other configurations are within the scopes of various embodiments.

The cell 100B further comprises one or more metal layers and via layers sequentially and alternatingly arranged over the VD and VG vias. The lowermost metal layer immediately over and in electrical contact with the VD and VG vias is a metal-zero (M0) layer. In other words, the M0 layer is the lowermost metal layer over, or the closest metal layer to, the active regions 101, 102 on the front side of the substrate. A next metal layer immediately over the M0 layer is a metal-one (M1) layer, or the like. Conductors in the M0 layer are referred to herein as M0 conductors, conductors in the M1 layer are referred to herein as M1 conductors, or the like. A via layer Vn is arranged between and electrically couple the Mn layer and the Mn+1 layer, where n is an integer form zero and up. For example, a via-zero (V0) layer is the lowermost via layer which is arranged between and electrically couple the M0 layer and the M1 layer. Other via layers are V1, V2, or the like. Metal layers, such as M0, M1, or the like, and via layers, such as V0, V1, or the like, on the front side of the substrate are referred to herein as front side metal layers and front side via layers.

Referring to FIG. 1C, the cell 100B comprises, in the M0 layer, M0 conductors 141, 142, 143, 144 along corresponding tracks M0_1, M0_2, M0_3, M0_4. The M0 conductors 141, 142, 143, 144 are configured to transfer signals, e.g., data, control, clock, or the like, among various circuit elements of an IC device, and are sometimes referred to as signal conductors. The corresponding tracks M0_1, M0_2, M0_3, M0_4 along which the M0 conductors 141, 142, 143, 144 are arranged are sometimes referred to as signal tracks.

The cell 100B further comprises, in the M0 layer, M0 conductors 140, 145 along corresponding tracks M0_VSS, M0_VDD. The M0 conductors 140, 145 are configured to supply power to various circuit elements of the IC device, and are sometimes referred to as power rails. For example, the power rail 140 is configured to supply a reference voltage, i.e., the ground voltage VSS, and is sometimes referred to as a VSS power rail. The power rail 145 is configured to supply a positive supply voltage, e.g., VDD, and is sometimes referred to as a VDD power rail. The corresponding tracks M0_VSS, M0_VDD along which the power rails 140, 145 are arranged are sometimes referred to as power tracks. Both signal tracks and power tracks in the M0 layer are sometimes commonly referred to as M0 tracks.

In some embodiments, the power rails 140, 145 extend continuously along the X-axis across multiple cells in a circuit region, such as the circuit region 103, to supply VDD and VSS to such multiple cells. In some embodiments, multiple power rails are elongated along the X-axis and arranged side by side along the Y-axis across a circuit region of an IC device to configure a power grid for powering circuit elements in the circuit region. In at least one embodiment, VDD power rails and VSS power rails in a power grid are arranged alternatingly along the Y-axis. In some embodiments, a pair of immediately adjacent power rails define therebetween a row of semiconductor devices, as described herein. Two power rails (or power tracks) are immediately adjacent along the Y-axis when there is no other power rail (or power track) therebetween. The power rails 140, 145 are examples of immediately adjacent power rails, and power tracks M0_VSS, M0_VDD are examples of immediately adjacent power tracks. Similarly, two signal tracks are immediately adjacent along the Y-axis when there is no other signal track therebetween. Further, two M0 tracks are immediately adjacent along the Y-axis when there is no other M0 track therebetween.

The tracks M0_VSS, M0_1, M0_2, M0_3, M0_4, M0_VDD and the corresponding M0 conductors 140-145 extend along the X-axis and are spaced from each other along the Y-axis. In the example configuration in FIG. 1C, the tracks M0_VSS, M0_1, M0_2, M0_3, M0_4, M0_VDD coincide with center lines of the corresponding M0 conductors 140-145. Further, the tracks M0_VSS, M0_VDD correspondingly coincide with the boundary lines 124, 122. The described coincidences are examples, and other configurations are within the scopes of various embodiments.

In at least one embodiment, all M0 conductors extend or are elongated along the same direction, e.g., along the X-axis, and are not elongated along the Y-axis. In some embodiments, M0 conductors in the M0 layer belong to the same mask. In at least one embodiment, M0 conductors in the M0 layer are separated into several masks to meet one or more design and/or manufacturing requirements. For example, the M0 conductors 140, 142, 144 belong to one mask and are schematically illustrated in the drawing with the label “M0_A,” whereas the M0 conductors 141, 143, 145 belong to another mask are schematically illustrated in the drawing with the label “M0_B.” The number of four signal tracks M0_1, M0_2, M0_3, M0_4 between a pair of immediately adjacent power tracks M0_VSS, M0_VDD is an example. Other configurations are within the scopes of various embodiments, as described herein.

In the example configuration in FIG. 1C, each of the M0 conductors 141, 142, 143, 144 extends toward, but remains inwardly spaced from, the edges 121, 123 of the boundary 120. In other words, the M0 conductors 141, 142, 143, 144 are completely arranged inside the boundary 120. For example, right edges (not numbered) of the M0 conductors 141, 142, 143, 144 are adjacent, but inwardly spaced from the edge 121 of the boundary 120, whereas left edges (not numbered) of the M0 conductors 141, 142, 143, 144 are adjacent, but inwardly spaced from the edge 123 of the boundary 120. This arrangement is an example, and other configurations are within the scopes of various embodiments. The power rails 140, 145 extend up to the edges 121, 123 of the boundary 120. This arrangement corresponds to the described configuration in which the power rails 140, 145 extend continuously across multiple cells.

The M0 conductor 140 overlaps and is electrically coupled to the VD via 133, and therefore, is electrically coupled by the VD via 133 to the source/drain region 136. The M0 conductor 141 overlaps and is electrically coupled to the VD via 134, and therefore, is electrically coupled by the VD via 134 to the source/drain region 137. The M0 conductor 142 overlaps and is electrically coupled to the VG via 131, and therefore, is electrically coupled by the VG via 131 to the gate region 110. The M0 conductor 145 overlaps and is electrically coupled to the VD via 132, and therefore, is electrically coupled by the VD via 132 to the source/drain region 135. The M0 conductors 141, 142 correspond to an output and an input of the inverter corresponding to the cell 100B. The M0 conductors 143, 144 are floating M0 conductors. In some embodiments, at least one of the M0 conductors 143, 144 is omitted.

The M0 conductors 141, 142, are examples of internal routing of a cell. In at least one embodiment, internal routing of a cell comprises conductors of one or more metal layers and/or vias of one or more via layers which are included in the layout of the cell, and which are configured to electrically couple various circuit elements or semiconductor devices in the cell into internal circuitry of the cell, and/or to form one or more inputs and/or outputs of the cell for electrically coupling the internal circuitry of the cell with circuitry external to the cell, e.g., to other cells of an IC device including the cell. For a simple cell, such as the cell 100B corresponding to an inverter, two M0 conductors are sufficient for internal routing. For more complex cells, e.g., a flip-flop, a greater number of M0 conductors and/or M0 tracks is used. In some embodiments, for internal routing of a complex cell, an M0 conductor is divided into several M0 conductors (not shown in FIG. 1C) spaced, and electrically isolated, from each other along the X-axis. In other words, several M0 conductors are arranged along the same M0 track, in one or more embodiments. An example of several M0 conductors are arranged along the same M0 track is described with respect to FIG. 9D. In some embodiments, internal routing of a cell is completed by M0 conductors, without requiring one or more conductors of a higher metal layer, such as the M1 layer, M2 layer, or the like. In some embodiments, internal routing of a cell comprises not only M0 conductors, but also one or more conductors of one or more higher metal layers and one or more vias of one or more corresponding via layers.

Each of the M0 conductors 140, 141, 142, 143, 144, 145 has a width (sometimes referred to as “metal width”) along the Y-axis. In the example configuration in FIG. 1C, the M0 conductors 141, 142, 143, 144, which are signal conductors, have a metal width W, and the M0 conductors 140, 145, which are power rails, have a metal width W_PG. The metal width of a power rail is sometimes referred to as a power rail width. The metal width W of signal conductors is smaller than the metal width W_PG of the power rails. In some embodiments, one or more signal conductors in a cell have a greater metal width than one or more other signal conductors in the same cell, as described herein.

Immediately adjacent M0 conductors, i.e., M0 conductors along a pair of immediately adjacent M0 tracks, are spaced from each other along the Y-axis by a metal spacing S. The metal spacing S is equal to or greater than a minimum metal spacing which is a predetermined design rule to be satisfied for manufacturability of an IC device including the cell. In at least one embodiment, the metal spacing S is equal to the minimum metal spacing. A sum of metal widths of M0 conductors over a cell, as well as metal spacings between the M0 conductors, is equal to the cell height H. In the example configuration in FIG. 1C, H=W_PG+4W+5S. Other configurations are within the scopes of various embodiments. For example, in some embodiments, immediately adjacent M0 conductors are spaced from each other by a metal spacing S greater than the minimum spacing, as described herein.

In some embodiments, a metal pattern configuration of a metal layer over a cell comprises a number of tracks over the cell, one or more metal widths of conductors along the tracks, one or more metal spacings between the conductors, and one or more sizes of vias coupled to the conductors. In at least one embodiment, the number of tracks over a cell corresponds to a number of signal tracks over the cell. For example, a metal pattern configuration of the M0 layer over a cell comprises a number of M0 tracks over the cell, one or more metal widths of M0 conductors along the tracks, and one or more metal spacings between the M0 conductors. In one or more embodiments, by varying one or more aspects of a metal pattern configuration of a metal layer, e.g., one or more of the number of tracks, metal widths, and metal spacings, it is possible to achieve an intended balance between routing efficiency and performance at various levels of cell complexity, as described herein. Several metal pattern configurations in accordance with one or more embodiments are described herein for the M0 layer. One or more of the described metal pattern configurations are applicable to other metal layers, such as a metal layer higher than the M0 layer on the front side, and/or a back side metal layer as described herein.

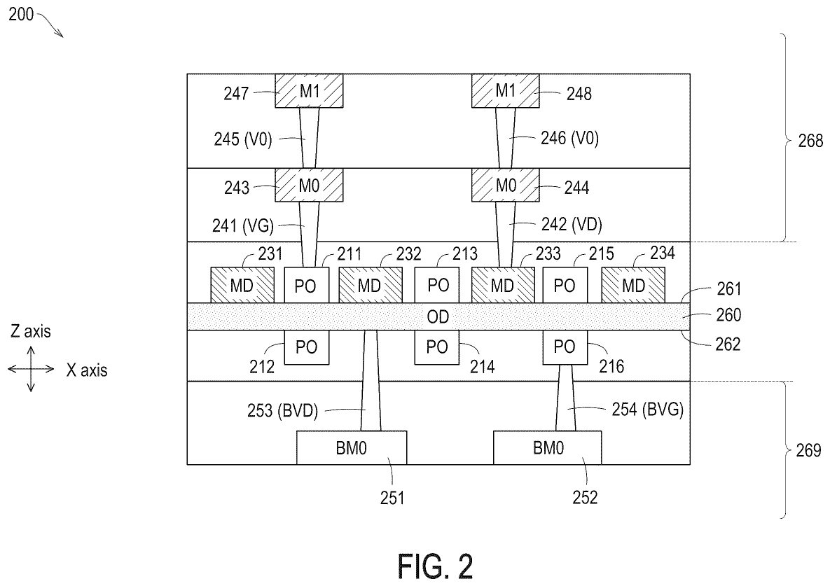

FIG. 2 is a schematic cross-sectional view of a circuit region of an IC device 200, in accordance with some embodiments. In some embodiments, the circuit region in FIG. 2 corresponds to the circuit region 103, and/or a circuit region that comprises one or more cells placed and routed as described herein. In at least one embodiment, the cells placed and routed in the circuit region in FIG. 2 corresponds to the cell 100B and/or one or more cells described herein.

As shown in FIG. 2, the IC device 200 comprises a substrate 260 over which circuit elements and structures corresponding to one or more cells described herein are formed. The substrate 260 has a first side 261 and a second side 262 opposite one another along a thickness direction of the substrate 260, i.e., along a Z-axis. In at least one embodiment, the first side 261 is referred to as “upper side” or “front side” or “device side,” whereas the second side 262 is referred to as “lower side” or “back side.” The substrate 260 comprises, in at least one embodiment, silicon, silicon germanium (SiGe), gallium arsenic, or other suitable semiconductor or dielectric materials.

The IC device 200 further comprises N-type and P-type dopants added to the substrate 260 to correspondingly form NMOS active regions and PMOS active regions. The NMOS active regions and PMOS active regions form corresponding active regions, and are collectively and schematically designated in FIG. 2 with the label “OD.” In some embodiments, isolation structures are formed between adjacent active regions. For simplicity, isolation structures are omitted from FIG. 2. In at least one embodiment, the active regions in FIG. 2 correspond to one or more of the active regions 101, 102 described with respect to FIG. 1B.

The IC device 200 further comprises various gate structures over the active regions on both the front side 261 and the back side 262. For example, a gate structure comprises a gate portion 211 on the front side 261, and a gate portion 212 integral with the gate portion 211 and on the back side 262. A further gate structure comprises a gate portion 213 on the front side 261, and a gate portion 214 integral with the gate portion 213 and on the back side 262. Another gate structure comprises a gate portion 215 on the front side 261, and a gate portion 216 integral with the gate portion 215 and on the back side 262. The described configuration is referred to as “gate-all-around.” Other configurations are within the scopes of various embodiments. For example, in at least one embodiment, gate structures are formed over the active regions on the front side 261, but not on the back side 262. One or more gate dielectric layers (not shown) are between the active regions and corresponding gate structures. Example materials of the gate dielectric layer or layers include HfO2, ZrO2, or the like. Example materials of the gate structures include polysilicon, metal, or the like. In some embodiments, at least one of the gate structures 211-216 corresponds to the functional gate region 110 and/or at least another one of the gate structures 211-216 corresponds to the dummy gate region 118 or 119, as described with respect to FIG. 1B. In at least one embodiment, gate structures corresponding to dummy gate regions include dielectric materials.

The IC device 200 further comprises MD contact structures for electrically coupling source/drains of various transistors in the active regions to other circuit elements. For example, MD contact structures 231-234 are illustrated in FIG. 2. In some embodiments, at least one of the MD contact structures 231-234 corresponds to one of the MD contact structures 135-137, as described with respect to FIG. 1B.

The IC device 200 further comprises VD vias and VG vias correspondingly over and in electrical contact with MD contact structures and gate structures. For example, as shown in FIG. 2, a VG via 241 is over and in electrical contact with the gate portion 211 of the corresponding gate structure, and a VD via 242 is over and in electrical contact with the MD contact structure 233. In some embodiments, the VG via 241 corresponds to the VG via 131, and/or the VD via 242 corresponds to one of the VD vias 132, 133, 134, as described with respect to FIG. 1B.

The IC device 200 further comprises, on the front side 261, an interconnect structure 268 which is over the VD and VG vias, and comprises a plurality of metal layers M0, M1, . . . and a plurality of via layers V0, V1, . . . arranged alternatingly in the thickness direction of the substrate 260, i.e., along the Z-axis. The interconnect structure 268 further comprises various interlayer dielectric (ILD) layers (not shown or numbered) in which the metal layers and via layers are embedded. The metal layers and via layers of the interconnect structure 268 are configured to electrically couple various elements or circuits of the IC device 200 with each other, and/or with external circuitry. For simplicity, metal layers and via layers above the M1 layer are omitted in FIG. 2.

For example, the M0 layer comprises M0 conductors 243, 244 correspondingly over and in electrical contact with the VG via 241 and VD via 242. In some embodiments, at least one of the M0 conductors 243, 244 corresponds to at least one of the M0 conductors 140-145, as described with respect to FIG. 1B. The V0 layer comprises V0 vias 245, 246 correspondingly over and in electrical contact with the M0 conductors 243, 244. The M1 layer comprises M1 conductors 247, 248 correspondingly over and in electrical contact with the V0 vias 245, 246. In at least one embodiment, the M0 conductors provide internal routing for a cell, and the V0 vias, M1 conductors and/or one or more higher via layers and metal layers provide an electrical connection to the cell from other cells of the IC device 200. Other configurations are within the scopes of various embodiments.

The IC device 200 further comprises, on the back side 262, a back side interconnect structure 269 which comprises at least one back side metal layer, such as a back-side-metal-zero (BM0) layer under the back side 262 of the substrate 260. On the back side 262 of the substrate 260, the BM0 layer is the uppermost metal layer under, or the closest metal layer to, the active regions or source/drains of the transistors of the IC device 200. In at least one embodiment, the IC device 200 comprises one or more further via layers, dielectric layers and metal layers (not shown) under the BM0 layer to form interconnections among circuit elements of the IC device 200 and/or to form electrical connections to external circuitry. Via layers and metal layers from the BM0 layer and below are sometimes referred to as back side via layers and back side metal layers. An example material of back side vias and back side metal layers includes metal. Other configurations are within the scopes of various embodiments. For simplicity, dielectric layers, back side via layers, and back side metal layers lower than the BM0 layer are omitted from FIG. 2.

In the example configuration in FIG. 2, the BM0 layer comprises an BM0 conductor 251 under and in electrical contact with a back side VD (BVD) via 253 which, in turn, is under and in electrical contact with the active regions on the back side 262. The BM0 layer further comprises an BM0 conductor 252 under and in electrical contact with a back side VG (BVG) via 254 which, in turn, is under and in electrical contact with the gate portion 216 of the corresponding gate structure. In some embodiments, at least one of the BM0 conductors 251, 252 is configured as a signal conductor or a power rail for a cell, as described herein. For example, in one or more embodiments, the IC device 200 comprises power rails configured by BM0 conductors on the back side which frees up M0 tracks and M0 conductors on the front side for signals. In other words, power rails such as the power rails 140, 145 described with respect to FIG. 1C are moved to the back side. In at least one embodiment, BM0 conductors include both signal conductors and power rails. In some embodiments where the gate structures are not formed under the active regions, the gate portions 212, 214, 216 and the corresponding BVG vias are omitted. In some embodiments, BVD vias are omitted.

In some embodiments, an example process of designing an IC (or IC device) utilizes one or more electronic design automation (EDA) tools for generating, optimizing and/or verifying a design of an IC before and/or after manufacturing the IC. At an IC design generation operation, a design of an IC is provided by a circuit designer. In some embodiments, the design of the IC comprises an IC schematic, i.e., an electrical diagram, of the IC. At a subsequent cell placement and routing operation, a layout diagram of the IC is generated based on the IC schematic. The cell placement and routing operation is referred to as Automatic Placement and Routing (APR) in at least one embodiment. In at least one embodiment, the IC layout diagram is generated by an EDA tool, such as an APR tool. Example operations by the APR tool include, but are not limited to, a placement operation and a routing operation. In a placement operation, the APR tool performs cell placement. Cells configured to provide pre-defined functions and having pre-designed layout diagrams are stored in one or more cell libraries. The APR tool accesses various cells from one or more cell libraries, and places the cells in an adjacent or abutting manner to generate an IC layout diagram corresponding to the IC schematic. In a routing operation, the APR tool performs routing to route various nets interconnecting the placed circuit elements. The routing is performed to ensure that the routed interconnections or nets satisfy a set of constraints. After the routing operation, the APR tool outputs the IC layout diagram including the placed circuit elements and routed nets. In some embodiments, one or more verifications are performed after the cell placement and routing operation. If one or more verifications are not passed, the IC schematic and/or the IC layout diagram are corrected and/or redesigned. If the verifications are passed, the IC layout diagram is output for manufacturing IC devices based on the IC layout diagram.

Some embodiments described herein are directed to an APR operation in which cells and row of cells having different metal pattern configurations in a same metal layer are used in a placement operation. Several metal pattern configurations in accordance with one or more embodiments are described herein for the M0 layer. However, other metal layers with different metal pattern configurations are within the scopes of various embodiments. For example, one or more of metal pattern configurations described herein are applicable to other metal layers, such as a metal layer higher than the M0 layer on the front side, and/or a back side metal layer, such as the BM0 layer or a lower back side metal layer.

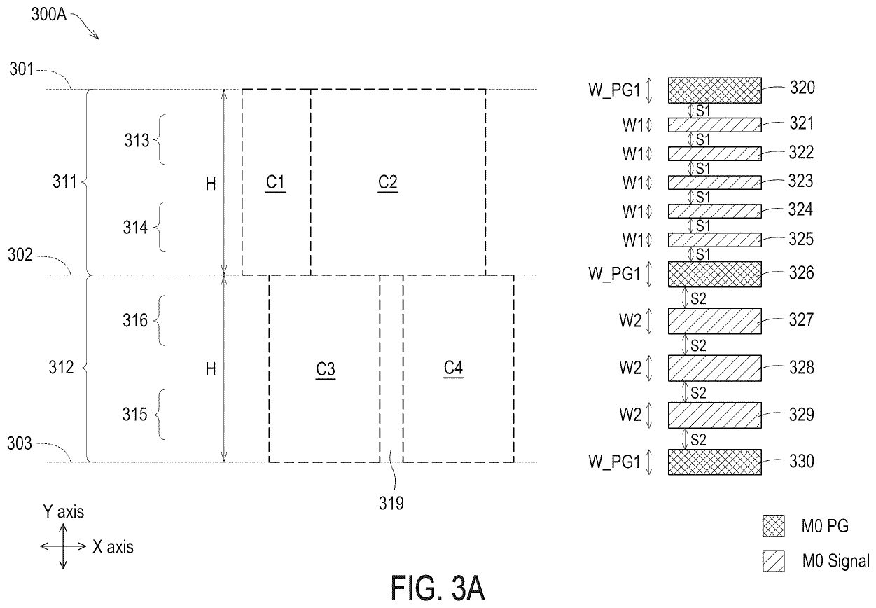

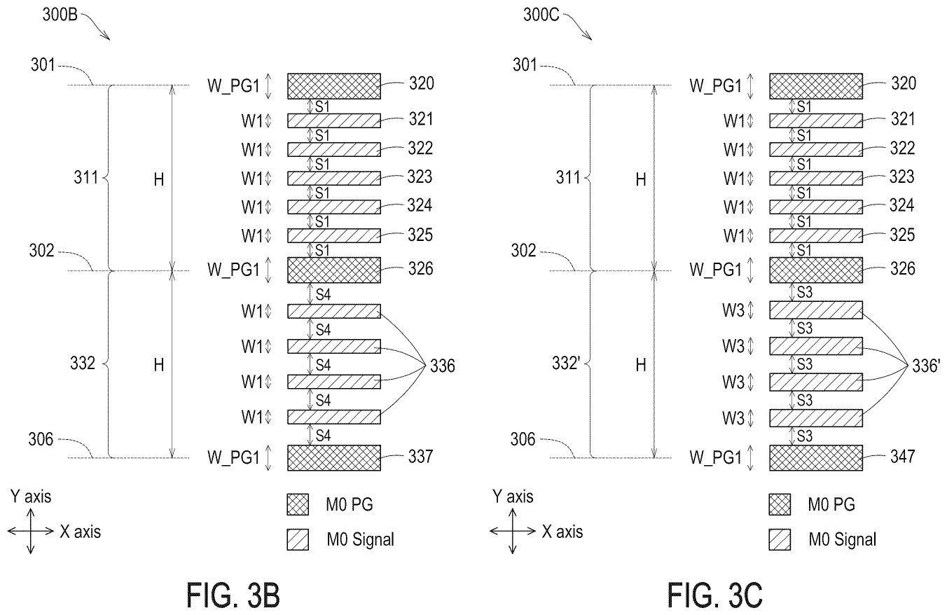

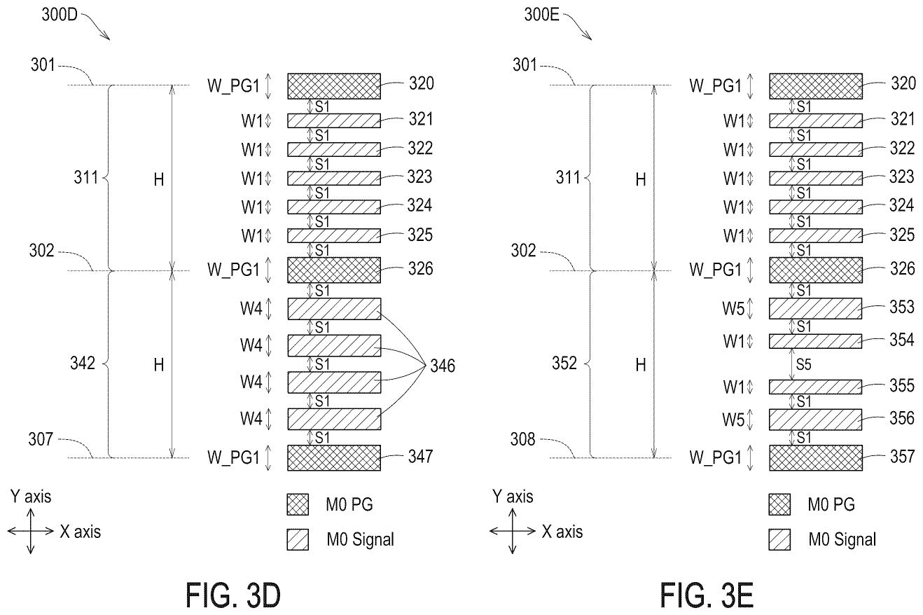

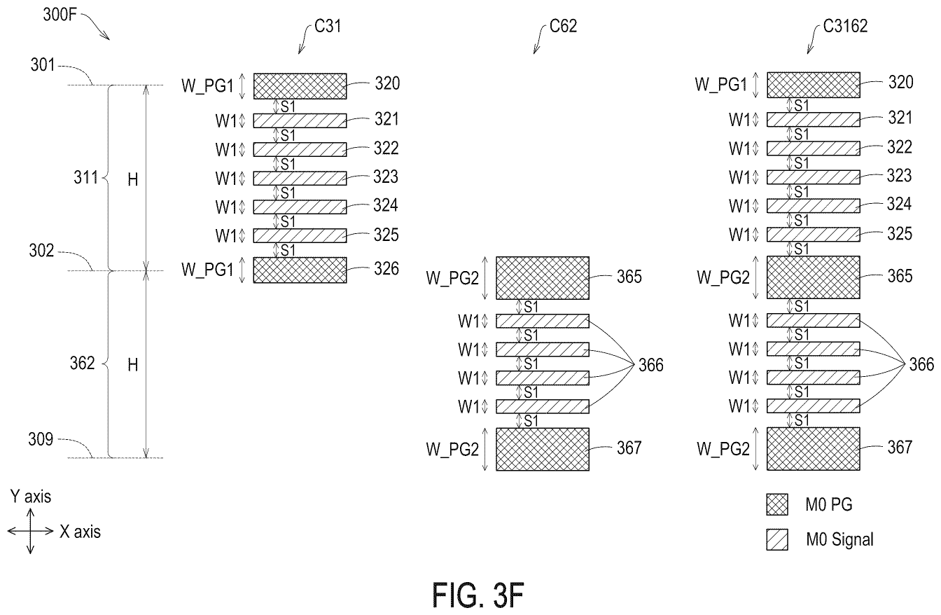

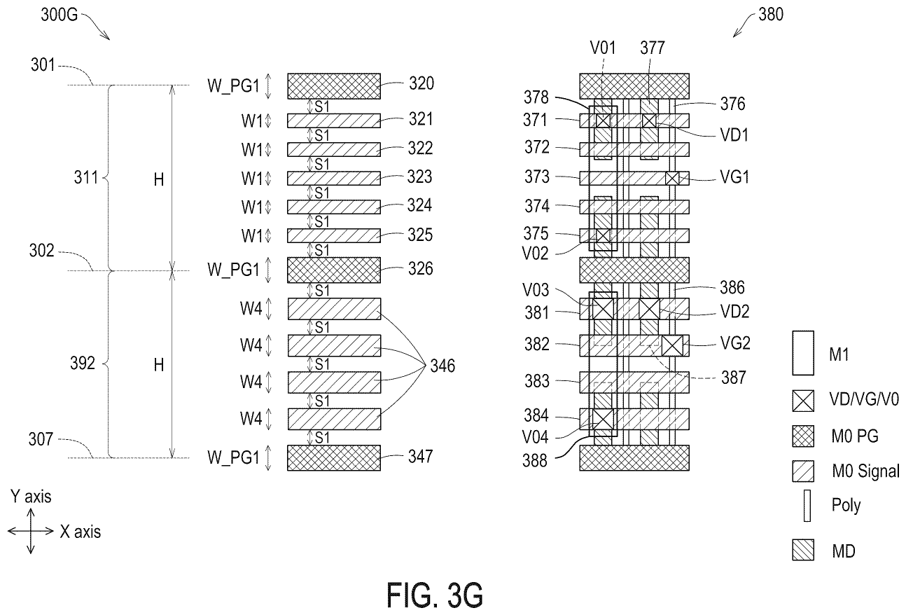

FIGS. 3A-3G are schematic views of corresponding layouts 300A-300G of circuit regions of one or more IC devices, in accordance with some embodiments. In some embodiments, at least one of the circuit regions represented by the layouts 300A-300G corresponds to the circuit region 103, and/or a circuit region that comprises one or more cells placed and routed as described herein. In at least one embodiment, at least one of the IC devices comprising such circuit regions corresponds to the IC device 200. In some embodiments, the layouts 300A-300G, as well as other layouts described herein with respect to various embodiments, are generated by an EDA system, such as an APR system, and/or stored in a non-transitory, computer-readable storage medium. Descriptions herein with respect to the layouts 300A-300G, as well as other layouts in accordance with various embodiments, are applicable to IC devices including circuit regions corresponding to the described layouts. For simplicity, corresponding components in FIGS. 3A-3G are designated by the same reference numerals, and several features, such as active regions and placed cells, are omitted from FIGS. 3B-3G. The layouts 300A-300G have various mixed row configurations, as described herein.

In FIG. 3A, the layout 300A comprises a plurality of rows of semiconductor devices. For simplicity, rows 311, 312 are illustrated in FIG. 3A whereas other rows are omitted. The rows 311, 312 are elongated along the X-axis and are arranged side-by-side along the Y-axis. The X-axis is an example of a first axis, and the Y-axis is an example of a second axis transverse to the first axis. In at least one embodiment, the semiconductor devices in the rows 311, 312 correspond to semiconductor devices or transistors described with respect to FIGS. 1B, 2. For example, the semiconductor devices in the row 311 are semiconductor devices included in cells C1, C2, or the like, placed in the row 311, and the semiconductor devices in the row 312 are semiconductor devices included in cells C3, C4, or the like, placed in the row 312. In at least one embodiment, each of the cells C1-C4 corresponds to the cell 100B and/or one or more further cells described herein. Various features of the cells C1-C4, such as active regions, gate regions, MD contact structures, VG vias, VD vias, M0 conductors, or the like, become corresponding features in the rows 311, 312 of the layout 300A.

Each of the rows 311, 312 has a pair of boundary lines spaced from each other along the Y-axis by a distance corresponding to a height of the row. For example, the row 311 has a pair of boundary lines 301, 302, and a corresponding height H between the boundary lines 301, 302, and the row 312 has a pair of boundary lines 302, 303, and the same corresponding height H between the boundary lines 302, 303. Thus, the rows 311, 312 have the same height (or row height) H which corresponds to the cell height H of the cells placed in the rows 311, 312. The row 311 is an example of a first row and the row 312 is an example of a second row, or vice versa. In some embodiments, at least one of the boundary lines 301-303 corresponds to a centerline of a power rail, as described with respect to FIG. 1C.

In the example configuration in FIG. 3A, the rows 311, 312 touch each other and share the common boundary line 302. Other configurations are within the scopes of various embodiments. For example, in at least one embodiment (not shown), two adjacent rows do not share a common boundary line, and are spaced from each other along the Y-axis by an empty space that contains no semiconductor devices. Such two rows are sometimes referred to as immediately adjacent non-touching rows. In some embodiments, two rows are considered adjoining each other when the two rows share a common boundary line (as shown in FIG. 3A) or when the two rows are immediately adjacent non-touching rows.

In an example placement operation, e.g., performed by an APR system, cells are placed in an IC layout in abutment with each other at their respective cell boundaries. For example, along the X-axis, the cell C1 is placed in abutment with the cell C2 along a common cell boundary. Along the Y-axis, the cell C1 is placed in abutment with the cell C3, and the cell C2 is placed in abutment with the cells C3, C4, along common cell boundaries defined by the boundary line 302 which, in one or more embodiments, is defined by a power rail as described herein. Cells are not always placed (or placeable) in abutment. For example, the cells C3, C4 are placed to be spaced from each other along the X-axis by an empty space that contains no semiconductor devices. The described placement operation is an example. Other placement operations are within the scopes of various embodiments.

Each of the rows 311, 312 comprises a first active region of a first conductivity type, and a second active region of a second conductivity type different from the first conductivity type, where the second active region is spaced from the first active region. For example, as schematically illustrated in FIG. 3A, the row 311 comprises a first active region 313 of a first conductivity type (e.g., P-type) and a second active region 314 of a second conductivity type (e.g., N-type), whereas the row 312 comprises a first active region 315 of the first conductivity type (e.g., P-type), and a second active region 316 of the second conductivity type (e.g., N-type). In some embodiments, the active regions 313, 315 correspond to the active region 101, and the active regions 314, 316 correspond to the active region 102.

Each of the active regions 313-316 is arranged in a region, e.g., a substrate region, a doped-region, or a well region, of a corresponding conductivity type. For example, each of the active regions 313, 315 is a P-type active region and is arranged in an N-type well region (not shown). In some embodiments, the N-type well region containing the active region 313 extends continuously across the boundary line 301 (upward in FIG. 3A) into another row of semiconductor devices (not shown), and/or the N-type well region containing the active region 315 extends continuously across the boundary line 303 (downward in FIG. 3A) into another row of semiconductor devices (not shown). The active regions 314, 316 are N-type active regions and are arranged in a common P-type substrate region (not shown) that extends continuously across the boundary line 302 from the row 311 into the row 312.

The layout 300A further comprises gate regions (not shown) extending along the Y-axis across the active regions 313-316. Such gate regions comprise one or more functional gate regions and/or one or more dummy gate regions. The functional gate regions configure, together with one or more of the active regions 313-316, various semiconductor devices or transistors, as described with respect to FIG. 1B.

The layout 300A further comprises a metal layer comprising a plurality of conductors arranged along a plurality of tracks elongated along the first axis, i.e., the X-axis. In the example configuration in FIG. 3A, the metal layer is the M0 layer. The description here is applicable to other metal layers, in accordance with various embodiments. In FIG. 3A, a first set of conductors 320-326 is configured in accordance with a first metal pattern configuration of the row 311, and a second set of conductors 326-330 is configured in accordance with a different, second metal pattern configuration of the row 312. For illustrative purposes, the conductors 320-330 are shown on a side of the corresponding rows 311, 312. In an actual layout, conductors extend along the X-axis over the rows and cells, as described with respect to FIG. 1C. For simplicity, conductors and corresponding tracks are designated by the same reference numerals. For example, the reference numeral “321” is used herein to refer to both a track and one or more conductors arranged along the track.

In accordance with the first metal pattern configuration of the row 311, there are five tracks 321-325 in the row 311 between two further tracks 320, 326 along the boundary lines 301, 302 of the row 311. The tracks 321-325 are signal tracks along which signal conductors are arranged. Signal conductors are schematically designated in the drawings by a label “M0 Signal.” The tracks 320, 326 are power tracks along which conductors configured as power rails are arranged. Power rails are schematically designated in the drawings by a label “M0 PG.” In some embodiments, at least one of the tracks 320, 326 coincides with a corresponding one of the boundary lines 301, 302 of the row 311. The signal conductors 321-325 along the signal tracks have a same metal width W1. The power rails 320, 326 along the power tracks have a same power rail width W_PG1. The signal conductors 321-325 are spaced from each other and/or from an adjacent one of the power rails 320, 326 by a metal spacing S1. In some embodiments, one or more of the metal width W1, power rail width W_PG1, metal spacing SI correspond to one or more of the metal width W, power rail width W_PG, metal spacing S described with respect to FIG. 1C. In at least one embodiment, the metal spacing S1 is equal to the minimum metal spacing.

In accordance with the second metal pattern configuration of the row 312, there are three tracks 327-329 in the row 312 between two further tracks 326, 330 along the boundary lines 302, 303 of the row 312. The tracks 327-329 are signal tracks along which signal conductors are arranged. The tracks 326, 330 are power tracks along which conductors configured as power rails are arranged. In some embodiments, at least one of the tracks 326, 330 coincides with a corresponding one of the boundary lines 302, 303 of the row 312. The signal conductors 327-329 along the signal tracks have a same metal width W2. The power rails 326, 330 along the power tracks have the same power rail width W_PG1. The signal conductors 327-329 are spaced from each other and/or from an adjacent one of the power rails 326, 330 by a metal spacing S2. In some embodiments, one or more of the metal width W2, power rail width W_PG1, metal spacing S2 correspond to one or more of the metal width W, power rail width W_PG, metal spacing S described with respect to FIG. 1C. In the example configuration in FIG. 3A, W2>W1, and S2>S1.

As described, the metal pattern configuration of the row 312 differs from the metal pattern configuration of the row 311 at least in the number of tracks in the row, metal width, and metal spacing. The described mixed row configuration of the layout 300A comprising five tracks in the row 311 and three tracks in the row 312 is an example. Other numbers of tracks in a row are within the scopes of various embodiments.

In the mixed row configuration of the layout 300A, in accordance with some embodiments, complex cells are configured, or designed, based on the metal pattern configuration of the row 311, and are placed in the row 311 for efficient internal routing, whereas non-complex cells are configured, or designed, based on the metal pattern configuration of the row 312, and are placed in the row 312 for improved performance. In some embodiments, a complex cell has a higher number of interconnects, and a non-complex cell has a lower number of interconnects. For example, a complex cell has a number of interconnects greater than a predetermined number, whereas a non-complex cell has a number of interconnects not greater than the predetermined number. In at least one embodiment, interconnects of a cell include interconnects for internal connection and interconnects for external connection. Interconnects for internal connection (or internal interconnects of the cell) comprise interconnects among various semiconductor devices or transistors of the cell. Interconnects for external connection comprise at least one input and at least one output of the cell. In at least one embodiment, for the purpose of determining cell complexity, interconnects in a metal layer, such as the M0 layer, are considered, whereas interconnects by MD contact structures or by adjacent transistors sharing a source/drain region are ignored. In at least one embodiment, a cell having more than five interconnects is considered a complex cell, whereas a cell having five or fewer interconnects is considered a non-complex cell. Other thresholds, or numbers of interconnects, for differentiating complex cells from non-complex cells are within the scopes of various embodiments. In some embodiments, more than two levels of cell complexity, e.g., complex cells, intermediate cells, and simple cells, are adopted. Examples of complex cells include, but are not limited to, flip-flops, latches, multiplexers, full adders, or the like. Examples of non-complex cells, such as simple cells and/or intermediate cells, include, but are not limited to, inverters, buffers, NAND gates, NOR gates, AND gates, OR gates, AOIs, or the like. Several non-limiting examples are described with respect to FIGS. 9A, 9C, 9E and/or FIGS. 9B, 9D, 9F.

As described herein, in some embodiments, complex cells configured based on the metal pattern configuration of the row 311 are placed in the row 311. The number of tracks in the row 311 is sufficiently high to accommodate a high number of interconnects of a complex cell, and makes it possible to achieve simplified or efficient internal routing for the complex cell. In some embodiments, the sufficiently high number of tracks in the row 311 permits completion of internal routing of complex cells within one metal layer, e.g., the M0 layer, without requiring additional resources from one or more other layers, e.g., higher metal layers and/or via layers.

On the other hand, it is possible to achieve internal routing of a non-complex cell having a low number of interconnects with fewer tracks. Therefore, in some embodiments, non-complex cells configured based on the metal pattern configuration of the row 312 are placed in the row 312 having a smaller number of tracks than the row 311. The smaller number of tracks in the row 312 permits metal width and/or metal spacing requirements to be relaxed, resulting in greater metal width W2 and metal spacing S2 of signal conductors than in the row 311. The greater metal width and metal spacing of the signal conductors reduce RC and voltage drop (IR drop) associated with the signal conductors, thereby improving speed or performance of the cells placed in the row 312, in one or more embodiments.

Other approaches use the same number of tracks for a metal layer in all rows with the same height. As a result, in the other approaches, when the number of tracks is high, performance of non-complex cells is potentially impeded due to unnecessarily reduced width and/or spacing of conductors, whereas when the number of tracks is low, internal routing of complex cells potentially becomes difficult and/or inefficient. A mixed row configuration in accordance with some embodiments provides an improvement over the other approaches, by achieving both efficient internal routing for complex cells placed in rows with a greater number of tracks, and increased performance for non-complex cells placed in rows with a lower number of tracks.

In some embodiments, the layout 300A comprises at least one high performance cells configured based on the metal pattern configuration of the row 312, and placed in one or more rows like the row 312, with fewer tracks, but with greater metal width and metal spacing. A high performance cell is a cell which is configured to achieve high speed or performance, and for which other considerations such as area and/or power consumption play a lesser role or are ignorable. The greater metal width and metal spacing in rows like the row 312 reduce RC and/or IR drop, improve performance, and are suitable for high performance cells, in one or more embodiments. In some embodiments, where a high performance cell is a complex cell which requires more than the number of tracks in a single row 312 for efficient internal routing, such a complex high performance cell is placed across multiple rows 312. As a result, it is possible in one or more embodiments to achieve both efficient internal routing and to ensure the intended high performance of the high performance cell. In an example, one or more high performance cells are arranged along a critical path in a layout of an IC device. A critical path is a timing sensitive path through which signals propagate during operation. In an example, a critical path is a path having a time delay that does not meet (i.e., is greater than) a timing requirement. In further example, a critical path is a path with a long time delay (in some situations, with the longest time delay) in a circuit region of an IC device, or in the whole IC device. A long time delay is a delay that might satisfy the timing requirement but is still greater than a predetermined threshold. Time delays of various paths in an IC design of an IC device are estimated during the design stage by, e.g., one or more simulations performed before or after an APR operation. Based on the result of such simulations, one or more critical paths are identified. In some embodiments, reducing the time delay of a critical path is either necessary to meet the timing requirement or desirable to improve performance of the IC device. Such an object is achievable in one or more embodiments by arranging high performance cells along a critical path.

Although it is described herein with respect to some embodiments to place complex cells in a row with a higher number of tracks and non-complex cells in a row with fewer tracks, it is possible in one or more embodiments to also place one or more non-complex cells in the row with a higher number of tracks. For example, inverters are non-complex cells and are mostly placed in rows with fewer tracks; however, in some embodiments, one or more inverters are also placed in rows with a higher number of tracks. The purpose is to achieve an intended density which is, in some situations, a design rule.

In FIG. 3B, the layout 300B comprises semiconductor devices arranged in a mixed row configuration including the row 311, and a row 332. The row 332 has a pair of boundary lines 302, 306, and the height H between the boundary lines 302, 306. Unlike the row 312 which has therein three signal tracks between a pair of power tracks, the row 332 has therein four signal tracks between a pair of power tracks. Signal conductors along the signal tracks of the row 332 are commonly designated as 336, and have the same metal width W1 as the signal conductors in the row 311. Power rails 326, 337 along the power tracks have the same power rail width W_PG1 as the power rails in the row 311. In the row 332, the signal conductors 336 are spaced from each other and/or from an adjacent one of the power rails 326, 337 by a metal spacing S4 greater than the metal spacing SI in the row 311.

As described, the metal pattern configuration of the row 332 differs from the metal pattern configuration of the row 311 at least in the number of tracks in the row, and metal spacing. The relaxed metal spacing S4 in the row 332 lowers coupling capacitance of the signal conductors 336, and therefore, improves performance of cells configured based on the metal pattern configuration of the row 332 and placed in the row 332, in one or more embodiments. In some embodiments, as described herein, complex cells are placed in the row 311 with the greater number of tracks, whereas non-complex c ells are placed in the row 332 with fewer tracks. In some embodiments, one or more advantages described herein are achievable by an IC layout comprising the layout 300B and/or IC devices manufactured in accordance with such IC layout.

In FIG. 3C, the layout 300C, in accordance with some embodiments, is a modified layout similar to the layout 300B. The layout 300C comprises semiconductor devices arranged in a mixed row configuration including the row 311, and a row 332′. The row 332′ comprises a modified metal pattern configuration of the row 332, and still comprises four tracks, but with different metal width and metal spacing. For example, in the row 332′, signal conductors 336′ have a metal width W3>W1, and are spaced from each other and/or from an adjacent one of the power rails 326, 337 by a metal spacing S3>S1. In at least one embodiment, W2>W3>W1, S2>S3>S1, and S4>S3. In some embodiments, one or more advantages described herein are achievable by an IC layout comprising the layout 300C and/or IC devices manufactured in accordance with such IC layout.

In FIG. 3D, the layout 300D comprises semiconductor devices arranged in a mixed row configuration including the row 311, and a row 342. The row 342 has a pair of boundary lines 302, 307, and the height H between the boundary lines 302, 307. Similar to the row 332, the row 342 has therein four signal tracks between a pair of power tracks. Signal conductors along the signal tracks of the row 342 are commonly designated as 346, and have a metal width W4>W1. Power rails 326, 347 along the power tracks have the same power rail width W_PG1 as the power rails in the row 311. In the row 342, the signal conductors 346 are spaced from each other and/or from an adjacent one of the power rails 326, 347 by the same metal spacing SI as the signal conductors in the row 311.

As described, the metal pattern configuration of the row 342 differs from the metal pattern configuration of the row 311 at least in the number of tracks in the row, and metal width. The relaxed metal width W4 in the row 342 lowers resistance of the signal conductors 346, and therefore, improves performance of cells configured based on the metal pattern configuration of the row 342 and placed in the row 342, in one or more embodiments. In some embodiments, as described herein, complex cells are placed in the row 311 with the greater number of tracks, whereas non-complex cells are placed in the row 342 with fewer tracks. In some embodiments, one or more advantages described herein are achievable by an IC layout comprising the layout 300D and/or IC devices manufactured in accordance with such IC layout.

In FIG. 3E, the layout 300E comprises semiconductor devices arranged in a mixed row configuration including the row 311, and a row 352. The row 352 has a pair of boundary lines 302, 308, and the height H between the boundary lines 302, 308. Similar to the row 332, the row 352 has therein four signal tracks between a pair of power tracks. Power rails 326, 357 along the power tracks have the same power rail width W_PG1 as the power rails in the row 311. Signal conductors 353-356 along the signal tracks of the row 352 have different metal widths and metal spacings. Specifically, each of the signal conductors 353, 356 has a metal width W5>W1, and is spaced from an adjacent signal conductor and an adjacent power rail by the same metal spacing S1 as the signal conductors in the row 311. The signal conductors 354, 355 have the same metal width W1 as the signal conductors in the row 311, and are spaced from each other by a metal spacing S5>S1.

As described, the metal pattern configuration of the row 352 differs from the metal pattern configuration of the row 311 at least in the number of tracks in the row, metal width, metal spacing, and non-uniform configurations of signal conductors. The relaxed metal width W5 of the signal conductors 353, 356 lowers resistance of the signal conductors 353, 356, whereas the relaxed metal spacing S5 between the signal conductors 354, 355 lowers coupling capacitance of the signal conductors 354, 355. As a result, it is possible in one or more embodiments to improve performance of cells configured based on the metal pattern configuration of the row 352 and placed in the row 352, in one or more embodiments.

In some embodiments, further performance improvements are achievable by configuring a cell to be placed in the row 352 to internally route a resistance critical net by at least one of the signal conductors 353, 356 with the wider metal width and lowered resistance, and/or to internally route a capacitance critical net by at least one of the signal conductors 354, 355 with the wider metal spacing and lowered capacitance. A resistance critical net is an interconnect which, during operation, is configured to handle a larger current than other interconnects in the cell. Therefore, low resistance of a resistance critical net is desirable to reduce IR drop, in accordance with some embodiments. An example resistance critical net of a cell includes, but is not limited to, an output of the cell. A capacitance critical net is an interconnect which, during operation, is configured to handle a time sensitive signal, such as an input signal or a clock signal, and is configured or desirable to have a lower time delay than other interconnects in the cell. Therefore, low capacitance of a capacitance critical net is desirable to reduce the time delay, in accordance with some embodiments. An example capacitance critical net of a cell includes, but is not limited to, an input of the cell. An example cell with an input routed through a signal conductor with a wider metal spacing and lowered capacitance, and an output routed through a further signal conductor with a wider metal width and lowered resistance is described with respect to FIG. 9B.

In some embodiments, as described herein, complex cells are placed in the row 311 with the greater number of tracks, whereas non-complex cells are placed in the row 352 with fewer tracks. In some embodiments, one or more advantages described herein are achievable by an IC layout comprising the layout 300E and/or IC devices manufactured in accordance with such IC layout.

In FIG. 3F, the layout 300F comprises semiconductor devices arranged in a mixed row configuration including the row 311, and a row 362. The metal pattern configuration of the row 311 is separately shown as C31, the metal pattern configuration of the row 362 is separately shown as C62, and the metal pattern configuration of the mixed row configuration comprising the row 311 and row 362 is shown as C3162.

As shown in the metal pattern configuration C62, the row 362 has a pair of boundary lines 302, 309, and the height H between the boundary lines 302, 309. Similar to the row 332, the row 362 has therein four signal tracks between a pair of power tracks. Signal conductors along the signal tracks of the row 362 are commonly designated as 366, and have the same metal width W1 and metal spacing SI as the signal conductors in the row 311. Power rails 365, 367 along the power tracks have a power rail width W_PG2>W_PG1. As shown in the metal pattern configuration C62, when the row 311 and the row 362 are arranged in abutment along the boundary line 302, the power rail 365 completely overlaps the power rail 326. This is an example, and other configurations are within the scopes of various embodiments. For example, in one or more embodiments, the power rail 365 partially overlaps the power rail 326, resulting in a power rail width greater than W_PG1 at the boundary between the row 311 and row 362.

As described, the metal pattern configuration of the row 362 differs from the metal pattern configuration of the row 311 at least in the number of tracks in the row, and power rail width. The increased power rail width W_PG2 of the power rails in the row 362 lowers resistance and IR drop of the power rails, and therefore, improves performance of cells configured based on the metal pattern configuration of the row 362 and placed in the row 362, in one or more embodiments. In some embodiments, as described herein, complex cells are placed in the row 311 with the greater number of tracks, whereas non-complex cells are placed in the row 362 with fewer tracks. In some embodiments, one or more advantages described herein are achievable by an IC layout comprising the layout 300F and/or IC devices manufactured in accordance with such IC layout.

In FIG. 3G, the layout 300G comprises semiconductor devices arranged in a mixed row configuration including the row 311 and a row 392. Except for via sizes, a metal pattern configuration of the row 392 is the same as the metal pattern configuration of the row 342 described with respect to the layout 300D. In the layout 300D in accordance with at least one embodiment, vias coupled to signal conductors of the metal width W1 in the row 311 have the same size as vias coupled to signal conductors of the greater metal width W4 (W4>W1) in the row 342. In the layout 300G, vias coupled to signal conductors of the greater metal width W4 in the row 342 have a larger size than vias coupled to signal conductors of the metal width W1 in the row 311, as shown in an example section 380 of the layout 300G.

The section 380 comprises, in the row 311, signal conductors 371-375 corresponding to the signal conductors 321-325, a gate region 376 coupled to the signal conductor 373 by a VG via VG1, an MD contact structure 377 coupled to the signal conductor 371 by a VD via VD1, and an M1 conductor 378 coupled to the signal conductors 371, 375 correspondingly by V0 vias V01, V02. The section 380 further comprises, in the row 392, signal conductors 381-384 corresponding to the signal conductors 346, a gate region 386 coupled to the signal conductor 382 by a VG via VG2, an MD contact structure 387 coupled to the signal conductor 381 by a VD via VD2, and an M1 conductor 388 coupled to the signal conductors 381, 384 correspondingly by V0 vias V03, V04.

A size of at least one of VG via, VD via, V0 via in the row 392 is larger than corresponding at least one of VG via, VD via, V0 via in the row 311. In the example configuration in FIG. 3G, via VG2, via VD2, and vias V03, V04 in the row 392 are correspondingly larger than via VG1, via VD1, and vias V01, V02 in the row 311.

As described, the metal pattern configuration of the row 392 differs from the metal pattern configuration of the row 311 at least in the number of tracks in the row, metal width, and via sizes. The relaxed metal width W4 and larger via sizes in the row 392 lower interconnect RC of the signal conductors in the row 392, and therefore, improve performance of cells configured based on the metal pattern configuration of the row 392 and placed in the row 392, in one or more embodiments. In some embodiments, as described herein, complex cells are placed in the row 311 with the greater number of tracks, whereas non-complex cells are placed in the row 392 with fewer tracks. In some embodiments, one or more advantages described herein are achievable by an IC layout comprising the layout 300G and/or IC devices manufactured in accordance with such IC layout.

Various mixed row configurations and/or metal pattern configurations described with respect to FIGS. 3A-3G are examples. Other mixed row configurations and/or metal pattern configurations are within the scopes of various embodiments. In at least one embodiment, a feature described with respect to one or more of FIGS. 3A-3G is combinable with another feature described with respect to one or more of FIGS. 3A-3G. For example, in at least one embodiment, different via sizes described with respect to FIG. 3G are combinable with signal conductors having different metal widths described with respect to FIG. 3E. In some embodiments, one or more features and/or metal pattern configurations described for a row with five tracks are applicable to a row with other than five tracks. In at least one embodiment, one or more features and/or metal pattern configurations described for a row with four tracks are applicable to a row with other than four tracks, e.g., a row with three tracks or a row with two tracks.

In some embodiments, a mixed row configuration comprising rows of the same height but with different metal pattern configurations in the M0 layer makes it possible to boost performance and reduce IR drop, without area penalty. In one or more embodiments, rows with a higher number of M0 tracks permit internal routing of complex cells to be effectively accomplished in the M0 layer and within an optimal chip area, without requiring additional routing resources in one or more higher metal layers and/or via layers. In some embodiments, rows with a lower number of M0 tracks permit M0 conductors to have wider metal width and/or metal spacing, which reduces RC and boosts performance of non-complex cells that require fewer routing resources, without any area penalty. In at least one embodiment, a reduced power rail width of an M0 power rail helps reducing IR drop in cells. In some embodiments, same logics (or same cells) are implemented (or placed) in multiple rows with different metal pattern configurations of the M0 layer, to satisfy a density requirement.

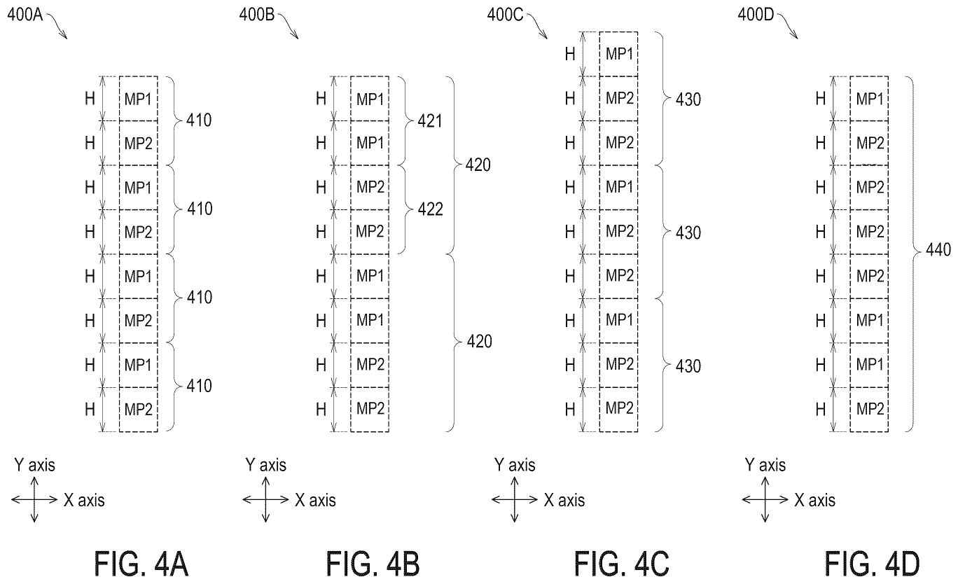

FIGS. 4A-4D, 5A-5B, 6A-6B, 7A-7B are schematic views of corresponding IC layouts 400A-400D, 500A-500B, 600A-600B, 700A-700B having various mixed row configurations, in accordance with some embodiments. In at least one embodiment, IC devices manufactured based on one or more of the IC layouts 400A-400D, 500A-500B, 600A-600B, 700A-700B correspond to the IC device 200. In some embodiments, one or more of the IC layouts 400A-400D, 500A-500B, 600A-600B, 700A-700B are generated by an EDA system, such as an APR system, and/or stored in a non-transitory, computer-readable storage medium. Descriptions herein with respect to one or more of the IC layouts 400A-400D, 500A-500B, 600A-600B, 700A-700B are applicable to the IC devices manufactured based on such one or more IC layouts. For simplicity, corresponding components in FIGS. 4A-4D, 5A-5B, 6A-6B, 7A-7B are designated by the same reference numerals. The layouts 400A-400D, 500A-500B, 600A-600B, 700A-700B have various mixed row configurations, as described herein.

In FIG. 4A, the IC layout 400A comprises, along the Y-axis, a repeating pattern of a set 410 of rows. The set 410 comprises a first row MP1 and a second row MP2 having the same height H. A metal pattern configuration of the first row MP1 is different from a metal pattern configuration of the second row MP2. As such, the first row MP1 and second row MP2 are arranged in a mixed row configuration. In some embodiments, the metal pattern configurations of the first row MP1 and second row MP2 correspond to any pair of different metal pattern configurations described herein, e.g., with respect to one or more of FIGS. 3A-3G. For example, the first row MP1 comprises therein N tracks, whereas the second row MP2 comprises therein fewer tracks, e.g., (N-1) tracks, (N-2) tracks, or the like. N is a natural number greater than 2. In some embodiments, N=5.

In some embodiments, as described herein, complex cells are placed in the first rows MP1 with the greater number of tracks, for efficient internal routing and/or optimized area of such complex cells. On the other hand, non-complex cells are placed in the second rows MP2 for improved performance and/or reduced power consumption. In a non-limiting example, a layout having a mixed row configuration with five tracks in a first row and four tracks in a second row achieves about 4.5% increase in speed and about 0.9% reduction in power consumption for non-complex cells in the second row, compared to a layout comprising five tracks in all rows. The layout having the mixed row configuration with five tracks in the first row and four tracks in the second row further achieves about 9.3% increase in speed and about 15.8% reduction in chip area for complex cells in the first row, compared to a layout comprising four tracks in all rows.

In FIG. 4B, the layout 400B comprises, along the Y-axis, a repeating pattern of a set 420 of rows. The set 420 comprises a first subset 421 of multiple first rows MP1, and a second subset 422 of multiple second rows MP2, all having the same height H. In some embodiments, the arrangement of multiple second rows MP2 in abutment with each other makes it possible to accommodate one or more complex, high performance cells, by placing such complex, high performance cells across the multiple, abutting second rows MP2, as described herein.

The IC layout 400A and IC layout 400B in FIGS. 4A, 4B are examples of mixed row configurations in which the number of first rows MP1 is equal to the number of second rows MP2. The IC layout 400C and IC layout 400D in FIGS. 4C, 4D are examples of mixed row configurations in which the number of first rows MP1 is different from the number of second rows MP2.

In FIG. 4C, the layout 400C comprises, along the Y-axis, a repeating pattern of a set 430 of rows. The set 430 comprises one first row MP1 and two second rows MP2. The two second rows MP2 abut each other along the Y-axis. The ratio of the number of first rows MP1 to the number of second rows MP2 is 1:2.

In FIG. 4D, the layout 400D comprises, along the Y-axis, a repeating pattern of a set 440 of rows. The set 440 comprises three first rows MP1 and five second rows MP2. The ratio of the number of first rows MP1 to the number of second rows MP2 is 3:5. Unlike the IC layout 400C where the second rows MP2 are grouped together in the set 430, the second rows MP2 are arranged at several locations along the Y-axis in the set 440. The first rows MP1 are also arranged at several locations along the Y-axis in the set 440. The described specific numbers of first rows MP1 and/or second rows MP2, their ratio, and/or the physical arrangements of the first rows MP1 and/or second rows MP2 in one or more of the sets 410-440 are examples. Other configurations are within the scopes of various embodiments.

In some embodiments, the numbers of first rows MP1 and second rows MP2 in an IC layout are determined by an EDA tool. For example, upon receiving an IC schematic (e.g., electrical circuitry) of an IC device for which an IC layout is to be generated, the EDA tool is configured to count or determine a number of complex cells and a number of non-complex cells from the IC schematic. Based on a ratio between the counted or determined number of complex cells and the counted or determined number of non-complex cells, the EDA tool is configured to select or generate a set of rows to be repeatedly arranged along the Y-axis in the IC layout. For example, when the ratio between the number of complex cells and the number of non-complex cells in the IC schematic is in a predetermined range around 1:1, the set 410 or the set 420 is selected for generating the IC layout. In at least one embodiment, a decision to select between the set 410 and the set 420 is performed by a human designer and/or by the EDA tool based on one or more other considerations. For another example, when the ratio between the number of complex cells and the number of non-complex cells in the IC schematic is in a predetermined range around 1:2, the set 430 is selected. In some embodiments, one or more advantages described herein are achievable by one or more of the IC layouts 400A-400D and/or IC devices manufactured in accordance with such IC layouts.

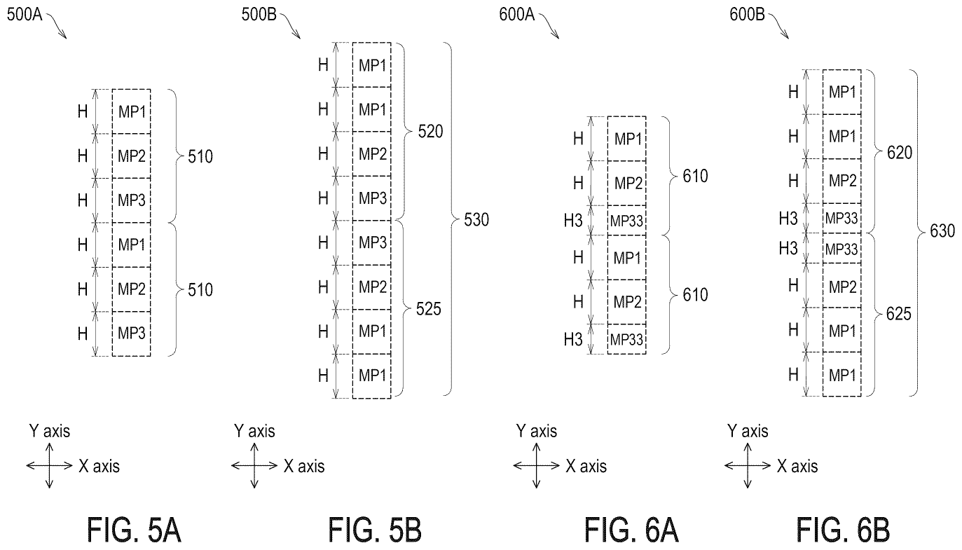

The IC layouts 400A-400D in FIGS. 4A-4D are examples of mixed row configurations including rows of the same height and with two different metal pattern configurations. The IC layouts 500A, 500B in FIGS. 5A, 5B are examples of mixed row configurations including rows of the same height and with three different metal pattern configurations. Other mixed row configurations with four or more metal pattern configurations are within the scopes of various embodiments.

In FIG. 5A, the IC layout 500A comprises, along the Y-axis, a repeating pattern of a set 510 of rows. The set 510 comprises a first row MP1, a second row MP2, and a third row MP3, all having the same height H. The first row MP1, second row MP2, third row MP3 have different metal pattern configurations. As such, the first row MP1, second row MP2, third row MP3 are arranged in a mixed row configuration. In some embodiments, the metal pattern configurations of the first row MP1, second row MP2, third row MP3 correspond to any three different metal pattern configurations described herein, e.g., with respect to one or more of FIGS. 3A-3G. For example, the first row MP1 comprises therein N tracks, the second row MP2 comprises therein (N-1) tracks, and the third row MP3 comprises therein (N-2) tracks, where N is a natural number greater than 2. In some embodiments, N=5.

In some embodiments, complex cells are placed in the first rows MP1 with the greater number of tracks, whereas non-complex cells are placed in the second row MP2 and/or third row MP3. In at least one embodiment, non-complex cells comprise intermediate cells and simple cells. An intermediate cell has a greater number of interconnects than a simple cell (but still lower than the number of interconnects of a complex cell). In an example, a complex cell has greater than five interconnects, an intermediate cell has between three and five interconnects, and a simple cell has two interconnects or fewer. Non-limiting, specific examples of a simple cell, an intermediate cell, and a complex cell are correspondingly described with respect to FIGS. 9A-9B, FIGS. 9C-9D, and FIGS. 9E-9F.

In at least one embodiment, complex cells are placed in the first rows MP1, intermediate cells are placed in the second rows MP2, and simple cells are placed in the third rows MP3, to achieve a balance among various effects, including, but not limited to, efficient internal routing, optimized area, improved performance, reduced power consumption, or the like. In some embodiments, one or more simple cells are also placed in one or more second rows MP2 and/or one or more intermediate cells are also placed in one or more third rows MP3, to achieve an intended density, as described herein.

The IC layout 500A in FIG. 5A is an example of a mixed row configuration in which the number of first rows MP1 is equal to the number of second rows MP2 and the number of third rows MP3. The IC layout 500B in FIG. 5B is an example of a mixed row configuration with different numbers of rows having different metal pattern configurations.

In FIG. 5B, the layout 500B comprises, along the Y-axis, a repeating pattern of a set 530 of rows. The set 530 comprises a first subset 520, and a second subset 525. Each of the first subset 520 and second subset 525 comprises two first rows MP1, one second row MP2, and one third row MP3. The first subset 520 and the second subset 525 are symmetrical across the X-axis. The ratio of the number of first rows MP1 to the number of second rows MP2 to the number of the third rows MP3 is 2:1:1. This ratio and the specific arrangement of the first rows MP1, second rows MP2, third rows MP3 in the set 530 are examples. Other configurations are within the scopes of various embodiments. In some embodiments, the numbers of first rows MP1, second rows MP2, third rows MP3 in an IC layout are determined from a corresponding IC schematic by an EDA tool, as described with respect to FIG. 4C. In some embodiments, one or more advantages described herein are achievable by one or more of the IC layouts 500A, 500B and/or IC devices manufactured in accordance with such IC layouts.

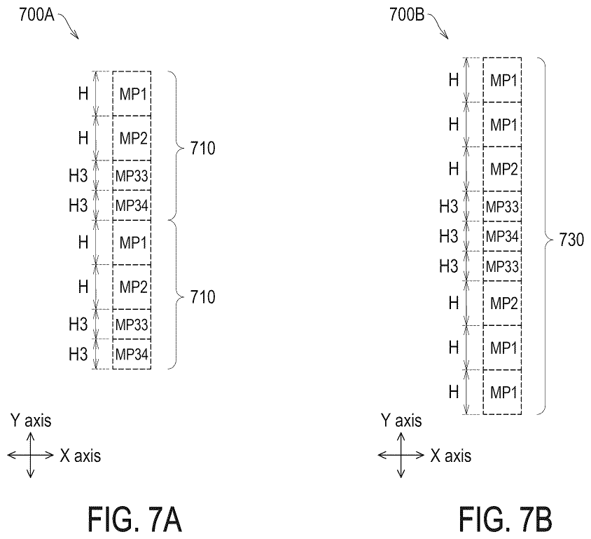

The IC layouts 400A-400D, 500A, 500B in FIGS. 4A-4D, 5A, 5B are examples of mixed row configurations including rows of the same height. The IC layouts 600A, 600B, 700A, 700B in FIGS. 6A-6B, 7A-7B are examples of mixed row configurations including rows of different heights.

In FIG. 6A, the IC layout 600A comprises, along the Y-axis, a repeating pattern of a set 610 of rows. The set 610 comprises a first row MP1, a second row MP2, and a third row MP33. The first row MP1 and second row MP2 have the same height H, and different metal pattern configurations as described with respect to one or more of FIGS. 4A-4D, 5A-5B. The third row MP33 has a height H3 different from the height H of the first row MP1 and second row MP2. In some embodiments, ratio between H and H3 is about 1.1 to 1.5.

In the example configuration in FIG. 6A, H3<H. In some embodiments, the third row MP33 with H3<H (sometimes referred to as a “short row”) includes cells with a smaller active region width than that of cells in the first row MP1, second row MP2. As a result, the cells (sometimes referred to as “short cells”) in the third row MP33 have lower speed/performance than the cells in the first row MP1, second row MP2, but occupy smaller areas and consume less power. Short cells and short rows are configured to provide non-critical circuits optimized for area and power, rather than speed/performance. To satisfy the same set of design rules at the smaller height H3 and smaller active region width, the third row MP33 has a metal pattern configuration different from that of the first row MP1, second row MP2 in one or more aspects as described herein.

In at least one embodiment (not shown), H3>H. In some embodiments, the third row MP33 with H3>H (sometimes referred to as a “tall row”) includes cells with a greater active region width than that of cells in the first row MP1, second row MP2. As a result, the cells (sometimes referred to as “tall cells”) in the third row MP33 have higher speed/performance than the cells in the first row MP1, second row MP2, but occupy greater areas and consume more power. Tall cells and tall rows are configured to provide critical circuits optimized for speed/performance, with area and power penalties. To satisfy the same set of design rules at the greater height H3 and greater active region width, the third row MP33 has a metal pattern configuration different from that of the first row MP1, second row MP2 in one or more aspects as described herein. In some embodiments (not shown), both short rows and tall rows are included in an IC layout.

The IC layout 600A in FIG. 6A is an example of a mixed row configuration in which the number of first rows MP1 is equal to the number of second rows MP2 and the number of third rows MP33. The IC layout 600B in FIG. 6B is an example of a mixed row configuration with different numbers of rows having different metal pattern configurations.

In FIG. 6B, the layout 600B comprises, along the Y-axis, a repeating pattern of a set 630 of rows. The set 630 comprises a first subset 620, and a second subset 625. Each of the first subset 620 and second subset 625 comprises two first rows MP1, one second row MP2, and one third row MP33. The first subset 620 and the second subset 625 are symmetrical across the X-axis. The ratio of the number of first rows MP1 to the number of second rows MP2 to the number of the third rows MP33 is 2:1:1. This ratio and the specific arrangement of the first rows MP1, second rows MP2, third rows MP33 in the set 630 are examples. Other configurations are within the scopes of various embodiments. In some embodiments, the numbers of first rows MP1, second rows MP2 in an IC layout are determined from a corresponding IC schematic by an EDA tool, as described with respect to FIG. 4C. In at least one embodiment, the number of the third row MP33 is also determined from the corresponding IC schematic by the EDA tool, e.g., by counting or determining the number of non-critical cells to be placed in the third rows MP33 being short rows, and/or by counting or determining the number of critical cells to be placed in the third rows MP33 being tall rows. In some embodiments, one or more advantages described herein are achievable by one or more of the IC layouts 600A, 600B and/or IC devices manufactured in accordance with such IC layouts.

The IC layouts 700A, 700B in FIGS. 7A, 7B additionally include rows of the same height H3 as the third rows MP33 in FIGS. 6A, 6B, but with a different metal pattern configuration.

In FIG. 7A, the IC layout 700A comprises, along the Y-axis, a repeating pattern of a set 710 of rows. The set 710 comprises a first row MP1, a second row MP2, a third row MP33, and a fourth row MP34. The first row MP1 and second row MP2 have the same height H, and different metal pattern configurations as described herein. The third row MP33 and the fourth row MP34 have the same height H3, and different metal pattern configurations. The metal pattern configurations of the third row MP33 and the fourth row MP34 differ in one or more aspects as described herein. In an example, the third row MP33 has M tracks, and the fourth row MP34 has (M-1) tracks. In the example configuration in FIG. 7A where H3<H, non-critical, complex cells are placed in the third row MP33, whereas non-critical, non-complex cells are placed in the fourth row MP34. In some embodiments (not shown), where H3>H, critical, complex cells are placed in the third row MP33, whereas critical, non-complex cells are placed in the fourth row MP34.

The IC layout 700A in FIG. 7A is an example of a mixed row configuration in which the number of first rows MP1 is equal to the number of second rows MP2, the number of third rows MP33, and the number of the fourth row MP34. The IC layout 700B in FIG. 7B is an example of a mixed row configuration with different numbers of rows having different metal pattern configurations.

In FIG. 7B, the layout 700B comprises, along the Y-axis, a repeating pattern of a set 730 of rows. The set 730 comprises four first rows MP1, two second rows MP2, two third rows MP33, and one fourth row MP34. The numbers and the specific arrangement of the first rows MP1, second rows MP2, third rows MP33, fourth row MP34 in the set 730 are examples. Other configurations are within the scopes of various embodiments. In some embodiments, the numbers of first rows MP1, second rows MP2, third rows MP33, fourth rows MP34 in an IC layout are determined from a corresponding IC schematic by an EDA tool, as described with respect to one or more of FIGS. 4C, 6B. In some embodiments, one or more advantages described herein are achievable by one or more of the IC layouts 700A, 700B and/or IC devices manufactured in accordance with such IC layouts.

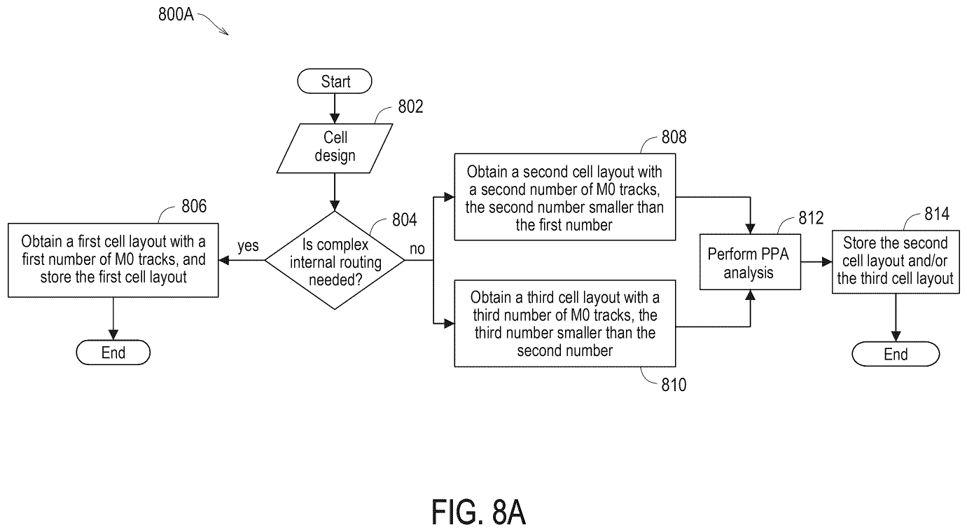

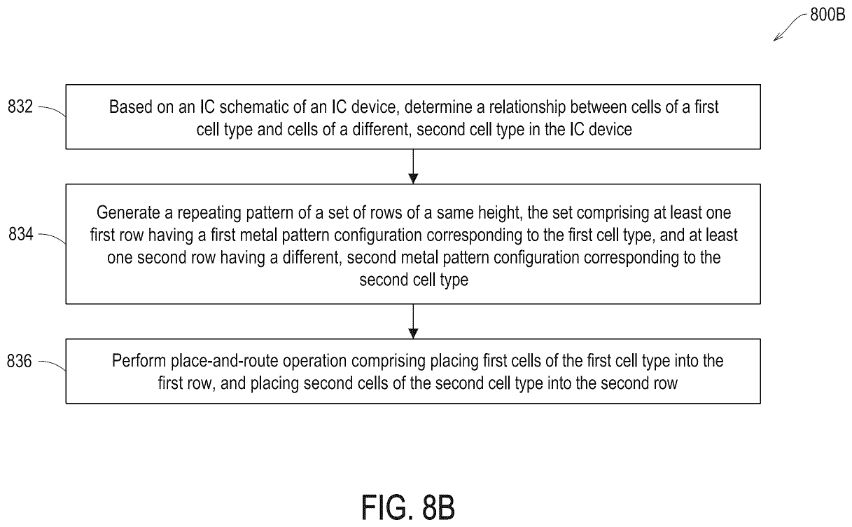

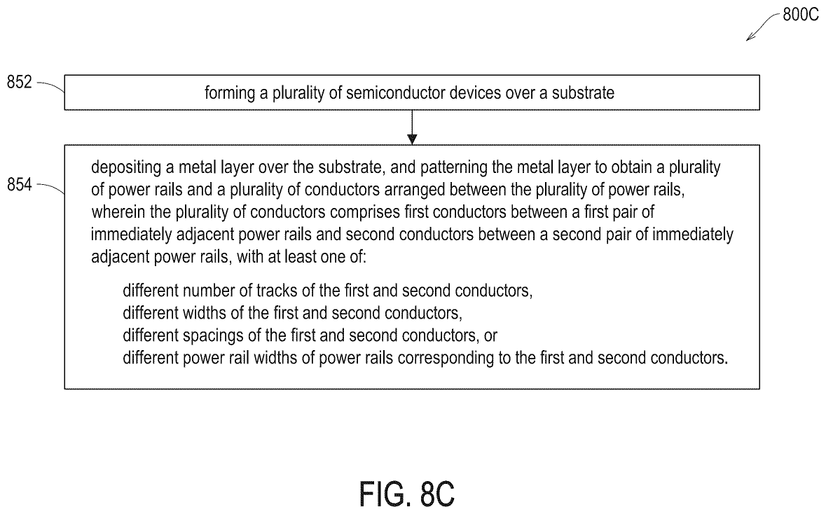

FIG. 8A is a flowchart of a method 800A, in accordance with some embodiments. In at least one embodiment, the method 800A is performed at least partially by a processor to build a cell library comprising cells usable for generating IC layouts with a mixed row configuration, as described herein.

At operation 802, a cell design for a cell is received. In some embodiments, the cell design comprises a circuit of the cell. Example circuits for various cells are described with respect to FIGS. 9A, 9C, 9E. In at least one embodiment, the cell design comprises a standard (or pre-developed) cell layout of the cell. An example standard cell layout is similar to that described with respect to FIGS. 1B, 1C or the row 311 in FIGS. 3A-3G, i.e., a metal pattern configuration (e.g., a number, a metal width, a metal spacing, or the like) of M0 tracks for internal routing of the cell is predetermined. Other standard cell layout configurations are within the scopes of various embodiments. In at least one embodiment, operation 802 is omitted.

At operation 804, it is determined whether complex internal routing is needed. In other words, it is determined whether the cell is a complex cell. In at least one embodiment, as described herein, whether the cell is a complex cell is determined based on a number of interconnects of the cell. The cell is a complex cell if the number of interconnects in the cell is greater than a predetermined number (or threshold). Otherwise, the cell is a non-complex cell. In at least one embodiment, the predetermined threshold is five. Other thresholds are within the scopes of various embodiments.

At operation 806, in response to determining at operation 804 that complex internal routing is needed or the cell is a complex cell, the process proceeds to operation 806. Otherwise, the process proceeds to operations 808, 810.

At operation 806, i.e., when the cell is a complex cell, a first cell layout is obtained for the cell. The first cell layout has a first number of M0 tracks therein. The obtained first cell layout is stored in a cell library on a non-transitory computer-readable storage medium. In some embodiments, when the cell design is a standard cell layout, the standard cell layout is adopted as the first cell layout. In at least one embodiment, when the cell design is a circuit of the cell, the first cell layout is generated based on a predetermined metal pattern configuration, as described herein.

At operation 808, i.e., when the cell is a non-complex cell, a second cell layout is obtained for the cell. The second cell layout has a same height as the first cell layout, and a second number of M0 tracks therein. The second number of M0 tracks in the second cell layout is smaller than the first number of M0 tracks in the first cell layout. In at least one embodiment, the second cell layout is generated for the cell in accordance with a metal pattern configuration having the second number of M0 tracks.

At operation 810, i.e., also when the cell is a non-complex cell, a third cell layout is obtained for the cell. The third cell layout has the same height as the first cell layout, and a third number of M0 tracks therein. The third number of M0 tracks in the third cell layout is smaller than the second number of M0 tracks in the second cell layout. In at least one embodiment, the third cell layout is generated for the cell in accordance with a metal pattern configuration having the third number of M0 tracks. In an example, the first cell layout has five M0 tracks therein, the second cell layout has four M0 tracks therein, and the third cell layout has three M0 tracks therein. Other configurations are within the scopes of various embodiments.

At operation 812, a PPA analysis is performed for the second cell layout and the third cell layout. In at least one embodiment, the PPA analysis comprises a simulation of a circuit built by using the second cell layout, and the same circuit built by using the third cell layout. In at least one embodiment, a result of the PPA analysis includes a quantitative evaluation of how each of the second cell layout and the third cell layout affects or contributes to one or more of power, performance, and area. In at least one embodiment, operation 812 is omitted.

At operation 814, at least one of the second cell layout or the third cell layout is stored in the cell library. In some embodiments, when a PPA analysis is performed at operation 812, the result of the PPA analysis indicates which of the second cell layout or the third cell layout is better in terms of PPA. The better cell layout is then stored in the cell library.

In at least one embodiment, both the second cell layout and the third cell layout are stored in the cell library in association with information corresponding to their respective PPA analysis results. Such information is useable later to determine which of the second cell layout or the third cell layout is to be used for building an IC layout. For example, when building an IC layout or a region thereof, a cell configured for improving power and/or area is required and the information stored in association with the second cell layout and the third cell layout indicates that the second cell layout is better than the third cell layout in terms of power and/or area, the second cell layout is selected to be placed in the IC layout or its region.

In at least one embodiment, when a PPA analysis at operation 812 is omitted, both the second cell layout and the third cell layout are stored in the cell library. One of the stored second cell layout and third cell layout is selected to be placed in a specific region of an IC layout being built, as the need arises. For example, when a cell is required in a row with three M0 tracks, the third cell layout with three M0 tracks is selected. Similarly, when a cell is required in a row with four M0 tracks, the second cell layout with four M0 tracks is selected.

In some embodiments, a standard cell layout, e.g., with five M0 tracks, for a non-complex cell is obtained and stored in the cell library together with the second cell layout and the third cell layout for the same cell design. For example, in one or more embodiments, the cell library comprises multiple cell layouts correspondingly with five M0 tracks, four M0 tracks, and three M0 tracks for the same non-complex cell, e.g., an inverter. A reason, as described herein, is to permit a non-complex cell to be placed in a row with a higher number (e.g., five) of M0 tracks to fulfill a density requirement.

In some embodiments, multiple second cell layouts and/or multiple third cell layouts are generated, PPA-analyzed, and/or stored. For example, multiple second cell layouts all of which have the same height and four M0 tracks are generated; however, with one or more differences in one or more of metal width, metal spacing, power rail width, via size, or the like, as described with respect to the rows 332, 342, 352, 362, 392 in FIGS. 3B-3G. In some embodiments, one or more advantages described herein are achievable by one or more IC layouts built from cells stored in the cell library and/or IC devices manufactured in accordance with such IC layouts.

FIG. 8B is a flowchart of a method 800B, in accordance with some embodiments. In at least one embodiment, the method 800B is performed at least partially by a processor, or an EDA system, to generate an IC layout with a mixed row configuration, e.g., from cells stored in the cell library as described with respect to FIG. 8A.

At operation 832, based on an IC schematic of an IC device, a relationship between cells of a first cell type and cells of a different, second cell type in the IC device is determined. For example, the first cell type corresponding to complex cells, and the second cell type corresponding to non-complex cells. In some embodiments, the relationship between cells of the first cell type and cells of the second cell type in the IC device is a ratio of a number of complex cells to a number of non-complex cells, as described herein.

At operation 834, based on the determined relationship, a repeating pattern of a set of rows of a same height is generated. The set of rows comprises at least one first row having a first metal pattern configuration corresponding to the first cell type, and at least one second row having a different, second metal pattern configuration corresponding to the second cell type. For example, when the determined ratio of the number of complex cells to the number of non-complex cells in the IC device is within a predetermined range around 1:1, one of the mixed row configurations described with respect to FIGS. 4A, 4B, 5A, 6A, 7A is selected as the set of rows to be repeatedly generated in the IC layout. When the determined ratio is in a predetermined range around another ratio, a corresponding mixed row configuration with a uneven distribution of rows, e.g., as described with respect to FIGS. 4C, 4D, 5B, 6B, 7B is selected as the set of rows to be repeatedly generated in the IC layout.

At operation 836, a place-and-route, or APR, operation is performed. The APR operation comprises placing first cells of the first cell type into the first rows, and placing second cells of the second cell types into the second rows. For example, as described herein, complex cells are placed in rows with a higher number of tracks, whereas non-complex cells are placed in rows with a lower number of tracks. In some embodiments, a routing operation is performed to couple the placed cells and to obtain an IC layout. The obtained IC layout is stored in a non-transitory computer-readable storage medium, and/or used for manufacturing IC devices. In some embodiments, one or more advantages described herein are achievable by IC layouts generated by the method 800B, and/or IC devices manufactured in accordance with such IC layouts.

FIG. 8C is a flowchart of a method 800C, in accordance with some embodiments. In some embodiments, the method 800C is a manufacturing process, which is performed using a manufacturing system discussed below, and in which at least one of (A) one or more photolithographic exposures are made, (B) one or more semiconductor masks are fabricated, or (C) one or more components in a layer of an IC device are fabricated. In some embodiments, IC devices are manufactured by the method 800C based on IC layouts which are generated by the method 800B and/or by using a cell library built in accordance with the method 800A.

At operation 852, a plurality of semiconductor devices is formed over a substrate, for example, as described with respect to FIG. 2.

At operation 854, a metal layer is deposited over the substrate, and patterned to obtain a plurality of power rails and a plurality of conductors arranged between the plurality of power rails. The plurality of conductors comprises first conductors between a first pair of immediately adjacent power rails to configure a first metal pattern configuration, and second conductors between a second pair of immediately adjacent power rails to configure a second metal pattern configuration. The first and second metal pattern configurations differ in at least one of different number of tracks of the first and second conductors, different widths of the first and second conductors, different spacings of the first and second conductors, or different power rail widths of power rails corresponding to the first and second conductors. In an example as described with respect to FIG. 2, an M0 layer is deposited and patterned over the substrate with the semiconductor devices formed thereon. The M0 layer includes a mixed row configuration with rows having different metal pattern configurations, as described with respect to FIGS. 3A-3G. In some embodiments, one or more advantages described herein are achievable by IC devices manufactured in accordance with the method 800C.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

FIG. 9A is a circuit diagrams of an inverter 900A, and FIG. 9B is a cell layout of a cell 900B corresponding to the inverter 900A, in accordance with some embodiments. The cell 900B is an example of a simple cell which is a non-complex cell, in one or more embodiments.

In FIG. 9A, the inverter 900A comprises a PMOS transistor P1 and an NMOS transistor N1 coupled in series between VDD and VSS. Gates of transistors P1, N1 are coupled to an input IN1. A source/drain of transistor P1 is coupled to a source/drain of transistor N1 and to an output ZN1. The inverter 900A has two interconnects corresponding to the input IN1 and output ZN1. In some embodiments, this number of two interconnects is used for the purpose of classifying an inverter cell, such as the cell 900B, as a non-complex cell or a simple cell, as described herein.

In FIG. 9B, the cell 900B comprises a boundary, active regions, gate regions, MD contact structures, VD vias, VG vias, M0 conductors similar to those described with respect to FIGS. 1B, 1C. Specifically, the cell 900B comprises active regions OD_P, OD_N, and four gate regions commonly designated as 920 and arranged between dummy gate regions 921, 922. The four gate regions 920 are electrically coupled together to configure an inverter of a driving strength of 4. The gate regions 920 configure transistor P1 with the active region OD_P, and transistor N1 with the active region OD_N. The cell 900B further comprises, in the M0 layer, M0 conductors 910-914. The M0 conductor 910 is a VDD power rail, the M0 conductor 914 is a VSS power rail, and the M0 conductors 911-913 are signal conductors on three signal tracks. For simplicity, MD contact structures and VD vias coupled to the power rails 910, 914 are omitted from FIG. 9B. The cell 900B further comprises four VG vias (one of which is designated as VG_1 in FIG. 9B) correspondingly coupling the four gate regions 920 to the M0 conductor 912 which configures the input IN1. The cell 900B further comprises VD vias VD_1, VD_2 coupling corresponding MD contact structures (not shown) to the M0 conductor 913 which configures the output ZN1. The cell 900B further comprises a V0 via V0_1 over the M0 conductor 913 for coupling the M0 conductor 913 to an M1 conductor (not shown) in a routing operation. In some embodiments, the via V0_1 is omitted from the cell 900B, and is generated by an APR tool in a routing operation. The boundary of the cell 900B is configured by the dummy gate regions 921, 922, and centerlines of the power rails 910, 914.

The M0 conductors 910-914 of the cell 900B are configured based on the metal pattern configuration of a row with three tracks in which the cell 900B is to be placed. The M0 conductors 911, 913 have a metal width W91 greater than a metal width W92 of the M0 conductor 912. The M0 conductor 912 is spaced from the adjacent M0 conductors 911, 913 by a metal spacing S92 which is greater than a metal spacing S91 by which the M0 conductors 911, 913 are correspondingly spaced from the power rails 910, 914. The described configuration of the M0 conductors 910-914 is similar to the metal pattern configuration of the row 352 in FIG. 3E. For example, similar to the metal pattern configuration described with respect to the row 352, the input IN1 of the cell 900B is configured by the M0 conductor 912 having a greater metal spacing from the adjacent M0 conductors, whereas the output ZN1 of the cell 900B is configured by the M0 conductor 913 having a greater metal width than the adjacent M0 conductor 912. In some embodiments, one or more advantages described herein are achievable by one or more IC layouts including the cell 900B and/or IC devices manufactured in accordance with such IC layouts.

FIG. 9C is a circuit diagrams of an AOI 900C, and FIG. 9D is a cell layout of a cell 900D corresponding to the AOI 900C, in accordance with some embodiments. The cell 900D is an example of an intermediate cell which is a non-complex cell, in one or more embodiments.

In FIG. 9C, the AOI 900C comprises PMOS transistors P2-P4, and NMOS transistors N2-N4. Transistors P2, P3 are coupled in parallel between VDD and a node No1. Transistor P4 is coupled between the node No1 and an output ZN2. Transistors N2, N3 are coupled in series between VSS and the output ZN2. Transistor N4 is coupled between VSS and the output ZN2. Gates of transistors P2, N2 are coupled to an input A1, gates of transistors P3, N3 are coupled to an input A2, and gates of transistors P4, N4 are coupled to an input B. The AOI 900C has five interconnects corresponding to three inputs A1, A2, B, the output ZN2, and the node No1. In some embodiments, this number of five interconnects is used for the purpose of classifying an AOI cell, such as the cell 900D, as a non-complex cell or an intermediate cell, as described herein.

In FIG. 9D, the cell 900D comprises a boundary, active regions, gate regions, MD contact structures, VD vias, VG vias, M0 conductors similar to those described with respect to FIGS. 1B, 1C, 9B. Specifically, the cell 900D comprises active regions OD_P, OD_N, and three gate regions commonly designated as 940 and arranged between dummy gate regions 941, 942. The gate regions 940 configure transistors P2-P4 with the active region OD_P, and transistors N2-N4 with the active region OD_N. The cell 900D further comprises, in the M0 layer, M0 conductors 930-936. The M0 conductor 930 is a VDD power rail, the M0 conductor 936 is a VSS power rail, and the M0 conductors 931-935 are signal conductors on four signal tracks. The M0 conductors 933, 934 are on the same track, and are physically and electrically separated from each other by a cut-M0 mask schematically designated as 939. For simplicity, MD contact structures and VD vias coupled to the power rails 930, 936 are omitted from FIG. 9D. The cell 900D further comprises VG vias VG_2, VG_3, VG_4 coupling the corresponding gate regions 940 to the M0 conductors 932, 933, 934 which correspondingly configure the inputs A1, A2, B. The cell 900D further comprises VD vias VD_3, VD_4 coupling corresponding MD contact structures (not shown) to the M0 conductor 931 which configures the node No1. The cell 900D further comprises VD vias VD_5, VD_6 coupling corresponding MD contact structures (not shown) to the M0 conductor 935 which configures the output ZN2. The cell 900D further comprises a V0 via V0_2 over the M0 conductor 933 for coupling the M0 conductor 933 to an M1 conductor (not shown) in a routing operation. In some embodiments, the via V0_2 is omitted from the cell 900D, and is generated by an APR tool in a routing operation. The boundary of the cell 900D is configured by the dummy gate regions 941, 942, and centerlines of the power rails 930, 936.

The M0 conductors 930-936 of the cell 900D are configured based on the metal pattern configuration of a row with four tracks in which the cell 900D is to be placed. The configuration of the M0 conductors 930-936 is similar to the metal pattern configuration of the row 352 in FIG. 3E and the configuration of the M0 conductors 910-914 in FIG. 9B. Specifically, the inputs A1, A2, B of the cell 900D are configured by the M0 conductors 932-934 having a greater metal spacing along the Y-axis from each other and from the adjacent M0 conductors 931, 935, whereas the output ZN2 of the cell 900D is configured by the M0 conductor 935 having a greater metal width than the adjacent M0 conductors 933. In some embodiments, one or more advantages described herein are achievable by one or more IC layouts including the cell 900D and/or IC devices manufactured in accordance with such IC layouts.

FIG. 9E is a circuit diagrams of a flip-flop 900E, and FIG. 9F is a cell layout of a cell 900F corresponding to the flip-flop 900E, in accordance with some embodiments. The cell 900F is an example of a complex cell, in one or more embodiments.

In FIG. 9E, the flip-flop 900E comprises various PMOS transistors and NMOS transistors coupled to form circuits 951-955, transmission gates TG1m, TG2m, TG1s, TG2s, and inverters INV1m, INV2m, INV1s, INV2s. The transmission gates TG1m, TG2m and inverters INV1m, INV2m configure a master latch circuit. The transmission gates TG1s, TG2s and inverters INV1s, INV2s configure a slave latch circuit. The flip-flop 900E comprises inputs D, SI, SE, CP, and an output Q. the flip-flop 900E has more than five interconnects, comprising the four inputs D, SI, SE, CP, the output Q, and various further interconnects in one or more of the circuits 951-955, master latch circuit, and slave latch circuit. In some embodiments, this high number of interconnects is used for the purpose of classifying a flip-flop cell, such as the cell 900F, as a complex cell, as described herein.

In FIG. 9F, the cell 900F comprises a boundary, active regions, gate regions, MD contact structures, VD vias, VG vias, M0 conductors similar to those described with respect to FIGS. 1B, 1C, 9B, 9D. For simplicity, features other than several M0 conductors are not numbered, and not described in detail herein.

The M0 conductors of the cell 900F are configured based on the metal pattern configuration of a row with five tracks in which the cell 900F is to be placed. Specifically, the cell 900F comprises, in the M0 layer, an M0 conductor 960 being a VDD power rail, an M0 conductor 967 being a VSS power rail, and various M0 conductors being signal conductors on five signal tracks. Among the signal conductors, M0 conductors 961-966 configure the inputs SE, CP, D, SI, and the output Q. The M0 conductors have the same metal width and the same metal spacing. The configuration of the M0 conductors in the cell 900F is similar to the metal pattern configuration of the row 311 in FIGS. 3A-3G. In some embodiments, one or more advantages described herein are achievable by one or more IC layouts including the cell 900F and/or IC devices manufactured in accordance with such IC layouts.

In some embodiments, at least one method(s) discussed above is performed in whole or in part by at least one EDA system. In some embodiments, an EDA system is usable as part of a design house of an IC manufacturing system discussed below.

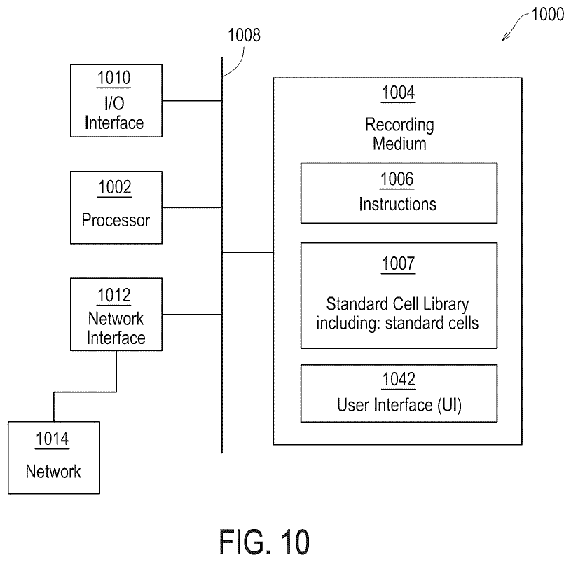

FIG. 10 is a block diagram of an electronic design automation (EDA) system 1000 in accordance with some embodiments.

In some embodiments, EDA system 1000 includes an APR system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable recording medium 1004. Recording medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable recording medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable recording medium 1004 are capable of connecting to external elements via network 1014. Processor 1002 is configured to execute computer program code 1006 encoded in computer-readable recording medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable recording medium 1004 is an electronic, magnetic, optical, electromagnetic, infrared, and/or a semiconductor system (or apparatus or device). For example, computer-readable recording medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 1004 includes a compact disk-read only memory (CD-ROM), a compact disk-read/write (CD-R/W), and/or a digital video disc (DVD).

In one or more embodiments, recording medium 1004 stores computer program code 1006 configured to cause system 1000 (where such execution represents (at least in part) the EDA tool) to be usable for performing a portion or all of the noted processes and/or methods. In one or more embodiments, recording medium 1004 also stores information which facilitates performing a portion or all of the noted processes and/or methods. In one or more embodiments, recording medium 1004 stores library 1007 of standard cells including such standard cells as disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable recording medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

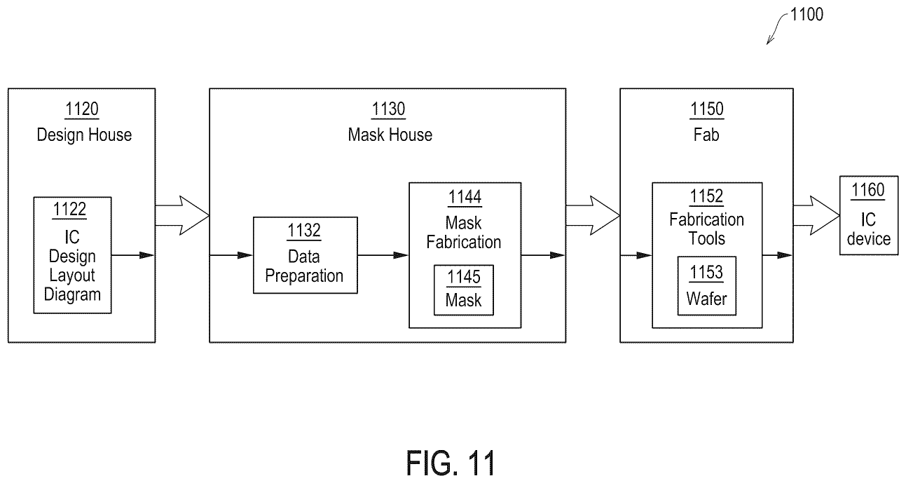

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place-and-route operation. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, an integrated circuit (IC) device comprises a plurality of rows of semiconductor devices, and a metal layer. The plurality of rows is elongated along a first axis and arranged side-by-side along a second axis transverse to the first axis. The metal layer comprises a plurality of conductors arranged along a plurality of tracks elongated along the first axis. Each of the plurality of rows comprises a first active region of a first conductivity type, and a second active region of a second conductivity type different from the first conductivity type, the second active region spaced from the first active region along the second axis. The plurality of rows comprises a first row and a second row which have a same first height along the second axis. The plurality of tracks comprises first tracks in the first row, and second tracks in the second row. The first number of the first tracks is different from a second number of the second tracks.

In some embodiments, a method of manufacturing an integrated circuit (IC) device comprises forming a plurality of semiconductor devices over a front side of a substrate, and depositing a metal layer over the substrate and patterning the metal layer. The patterned metal layer comprises a plurality of power rails elongated along a first axis and spaced from each other by a first height along a second axis transverse to the first axis, and a plurality of conductors arranged between the plurality of power rails and electrically coupling the plurality of semiconductor devices into a plurality of circuits of the IC device. The plurality of conductors comprises first conductors between a first pair of immediately adjacent power rails among the plurality of power rails, and second conductors between a second pair of immediately adjacent power rails among the plurality of power rails. The metal layer includes at least one of (a) a first number of tracks along which the first conductors are arranged is different from a second number of tracks along which the second conductors are arranged, (b) along the second axis, the first conductors have a first width, and the second conductors have a second width different from the first width, (c) along the second axis, the first conductors are spaced from each other by a first spacing, and the second conductors are spaced from each other by a second spacing different from the first spacing, or (d) along the second axis, a first power rail in the first pair of immediately adjacent power rails has a first power rail width, and a second power rail in the second pair of immediately adjacent power rails has a second power rail width different from the first power rail width.

In some embodiments, a method is performed at least partially by a processor and comprises, in response to a number of interconnects in a cell for a layout of an integrated circuit (IC) device being greater than a predetermined threshold, obtaining a first layout of the cell and storing the first layout in a cell library on a non-transitory computer-readable storage medium. The first layout has a first height and a first number of metal-zero (M0) tracks in the first layout. The method further comprises, in response to the number of interconnects in the cell being not greater than the predetermined threshold, obtaining a second layout of the cell and a third layout of the cell. The second layout has the first height and a second number of M0 tracks in the second layout, the second number smaller than the first number. The third layout has the first height and a third number of M0 tracks in the third layout, the third number smaller than the second number. The method further comprises storing at least one of the second layout or the third layout in the cell library.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit (IC) device, comprising:
a plurality of rows of semiconductor devices, the plurality of rows elongated along a first axis and arranged side-by-side along a second axis transverse to the first axis; and
a metal layer comprising a plurality of conductors arranged along a plurality of tracks elongated along the first axis,
wherein
each of the plurality of rows comprises:
a first active region of a first conductivity type, and
a second active region of a second conductivity type different from the first conductivity type, the second active region spaced from the first active region along the second axis,
the plurality of rows comprises a first row and a second row which have a same first height along the second axis,
the plurality of tracks comprises first tracks in the first row, and second tracks in the second row, and
a first number of the first tracks is different from a second number of the second tracks.

2. The IC device of claim 1, wherein
the IC device comprises a plurality of metal layers among which the metal layer is closest to the first and second active regions on a front side or on a back side of the IC device.

3. The IC device of claim 1, wherein
the plurality of conductors comprises:
first conductors arranged along the first tracks, and
second conductors arranged along the second tracks, and
at least one of:
along the second axis, the first conductors have a first width, and the second conductors have a second width different from the first width,
along the second axis, the first conductors are spaced from each other by a first spacing, and the second conductors are spaced from each other by a second spacing different from the first spacing, or
the IC device further comprises first vias electrically coupled to the first conductors and having a first via size, and second vias electrically coupled to the second conductors and having a second via size different from the first via size.

4. The IC device of claim 1, wherein
the plurality of conductors comprises a plurality of power rails,
the first tracks in the first row are arranged between a first pair of immediately adjacent power rails among the plurality of power rails,
the second tracks in the second row are arranged between a second pair of immediately adjacent power rails among the plurality of power rails,
the plurality of conductors comprises:
first conductors arranged along the first tracks, and
second conductors arranged along the second tracks, and
at least one of:
along the second axis, the first conductors have a first width, and the second conductors have a second width different from the first width,
along the second axis, the first conductors are spaced from each other by a first spacing, and the second conductors are spaced from each other by a second spacing different from the first spacing,
along the second axis, a first power rail in the first pair of immediately adjacent power rails has a first power rail width, and a second power rail in the second pair of immediately adjacent power rails has a second power rail width different from the first power rail width, or
the IC device further comprises first vias electrically coupled to the first conductors and having a first via size, and second vias electrically coupled to the second conductors and having a second via size different from the first via size.

5. The IC device of claim 1, wherein
the plurality of conductors comprises:
first conductors arranged along the first tracks, and
second conductors arranged along the second tracks,
along the second axis, the first conductors have a first width, and are spaced from each other by a first spacing, and
the second conductors comprise:
at least one second conductor which has, along the second axis, a second width greater than the first width, and
a pair of immediately adjacent second conductors which are spaced from each other by a second spacing different from the first spacing.

6. The IC device of claim 5, wherein
the at least one second conductor comprises an output of a circuit of the IC device, and
at least one of the pair of immediately adjacent second conductors comprises an input of the circuit, and has along the second axis a width smaller than the second width.

7. The IC device of claim 1, wherein
the plurality of rows comprises, along the second axis, a repeating pattern of a set of rows, and
the set of rows comprises the first row and the second row.

8. The IC device of claim 1, wherein
the plurality of rows comprises, along the second axis, a repeating pattern of a set of rows, and
the set of rows comprises:
a first subset of rows each having the first height along the second axis, and the first number of tracks among the plurality of tracks, wherein the first subset of rows comprises the first row, and
a second subset of rows each having the first height along the second axis, and the second number of tracks among the plurality of tracks, wherein the second subset of rows comprises the second row.

9. The IC device of claim 8, wherein
a number of rows in the first subset of rows is equal to a number of rows in the second subset of rows.

10. The IC device of claim 8, wherein
a number of rows in the first subset of rows is different from a number of rows in the second subset of rows.

11. The IC device of claim 1, wherein
the plurality of rows comprises, along the second axis, a repeating pattern of a set of rows,
the set of rows comprises:
the first row,
the second row, and
a third row which has the first height along the second axis,
the plurality of tracks further comprises third tracks in the third row, and
a third number of the third tracks is different from the first number of the first tracks and the second number of the second tracks.

12. The IC device of claim 1, wherein
the plurality of rows comprises, along the second axis, a repeating pattern of a set of rows,
the set of rows comprises:
the first row,
the second row, and
a third row which has along the second axis a second height different from the first height.

13. The IC device of claim 12, wherein
the set of rows further comprises:
a fourth row which has along the second axis the second height,
the plurality of tracks further comprises third tracks in the third row, and fourth tracks in the fourth row, and
a third number of the third tracks is different from a fourth number of the fourth tracks.

14. The IC device of claim 1, wherein
the plurality of conductors comprises:
first conductors arranged along the first tracks, and
second conductors arranged along the second tracks,
the semiconductor devices in the first row are electrically coupled by the first conductors into a first circuit,
the semiconductor devices in the second row are electrically coupled by the second conductors into a second circuit different from the first circuit,
the first number of the first tracks in the first row is greater than the second number of the second tracks in the second row, and
a number of the first conductors in the first circuit is greater than a number of the second conductors in the second circuit.

15. A method of manufacturing an integrated circuit (IC) device, comprising:
forming a plurality of semiconductor devices over a front side of a substrate; and
depositing a metal layer over the substrate, and patterning the metal layer to obtain
a plurality of power rails elongated along a first axis, and spaced from each other by a first height along a second axis transverse to the first axis, and
a plurality of conductors arranged between the plurality of power rails, and electrically coupling the plurality of semiconductor devices into a plurality of circuits of the IC device, wherein
the plurality of conductors comprises:
first conductors between a first pair of immediately adjacent power rails among the plurality of power rails, and
second conductors between a second pair of immediately adjacent power rails among the plurality of power rails, and
at least one of:
a first number of tracks along which the first conductors are arranged is different from a second number of tracks along which the second conductors are arranged,
along the second axis, the first conductors have a first width, and the second conductors have a second width different from the first width,
along the second axis, the first conductors are spaced from each other by a first spacing, and the second conductors are spaced from each other by a second spacing different from the first spacing, or
along the second axis, a first power rail in the first pair of immediately adjacent power rails has a first power rail width, and a second power rail in the second pair of immediately adjacent power rails has a second power rail width different from the first power rail width.

16. The method of claim 15, further comprising:
depositing and patterning a plurality of metal layers over the front side or a back side of the substrate, the back side opposite to the front side in a thickness direction of the substrate,
wherein, among the plurality of metal layers, the metal layer is closest to the semiconductor devices.

17. The method of claim 15, further comprising:
forming first vias electrically coupled to the first conductors, and second vias electrically coupled to the second conductors,
wherein a first via size of the first vias is different from a second via size of the second vias.

18. The method of claim 15, wherein
the second conductors comprise:
at least one second conductor which has, along the second axis, a second width greater than the first width, and
a pair of immediately adjacent second conductors which are spaced from each other by a second spacing different from the first spacing.

19. A method, performed at least partially by a processor and comprising:
in response to a number of interconnects in a cell for a layout of an integrated circuit (IC) device being greater than a predetermined threshold,
obtaining a first layout of the cell, the first layout having a first height and a first number of metal-zero (M0) tracks in the first layout, and
storing the first layout in a cell library on a non-transitory computer-readable storage medium; and
in response to the number of interconnects in the cell being not greater than the predetermined threshold,
obtaining a second layout of the cell, the second layout having the first height and a second number of M0 tracks in the second layout, the second number smaller than the first number,
obtaining a third layout of the cell, the third layout having the first height and a third number of M0 tracks in the third layout, the third number smaller than the second number, and
storing at least one of the second layout or the third layout in the cell library.

20. The method of claim 19, wherein
at least one of said obtaining the first layout, said obtaining the second layout, or said obtaining the third layout comprises arranging first through third conductors correspondingly along first through third M0 tracks, wherein
the second M0 track is between and immediately adjacent to the first M0 track and the third M0 track,
the first conductor has a first width greater than a second width of the second conductor and the third conductor, and corresponds to an output of the cell,
a first spacing between the first conductor and the second conductor is smaller than a second spacing between the second conductor and the third conductor, and
at least one of the second conductor or the third conductor corresponds to an input of the cell.
